(19) United States
(12) Patent Application Publication
(10) Pub. No.: US 2024/0169121 A1
(43) Pub. Date: May 23, 2024

(54) Predictive Risk Assessment In Manufacturing System Modeling

(71) Applicant: X-Act Science, Inc., Road Town (VG)

(72) Inventors: Nabil A. Abu El Ata, New York, NY (US); Annie Drucbert, New York, NY (US); Tomy Abu El Ata, New York, NY (US)

(21) Appl. No.: 18/503,966

(22) Filed: Nov. 7, 2023

Related U.S. Application Data
(60) Provisional application No. 63/382,809, filed on Nov. 8, 2022.

(51) Int. Cl. G06F 30/20

(52) U.S. Cl. CPC G06F 30/20

(57) ABSTRACT

Operation of a manufacturing system is evaluated through mathematical modeling. The system is modeled via a resource graph defining the physical resources of the system, a process graph defining services performed by the system, and a mapping between the resource graph and process graph. Performance metrics of the system are modeled by simulating performance of the services as a function of the resource graph and the process graph under plural sets of operational parameters. A risk may be identified based on the modeled performance metrics, the risk indicating a change in the performance metrics that exceeds a predetermined threshold. A set of operational parameters associated with an outcome absent the risk may then be identified. A modification to the manufacturing system is determined based on this discovery, enabling the system to be optimized to avoid the risk.

### RELATED APPLICATION

This application claims the benefit of U.S. Provisional Application No. 63/382,809, filed on Nov. 8, 2022. The entire teachings of the above application are incorporated herein by reference.

### BACKGROUND

Manufacturing systems are intricate and multifaceted entities that encompass a wide array of processes, machines, tools, materials, and human factors. For centuries, industries have endeavored to perfect their manufacturing processes to reduce costs, improve quality, and increase output. With the advent of the digital era, manufacturing systems have grown increasingly complex, necessitating robust tools and techniques to oversee and fine-tune these processes.

Historically, trial and error methods were predominantly used to optimize manufacturing processes. Such methods, although useful, often led to increased costs, wasted resources, and extended timeframes before achieving the desired efficiency. As manufacturing systems became more intricate, the need for methods to predict, analyze, and improve system performance became evident.

In recent decades, various simulation tools and methodologies have emerged to model manufacturing processes. Computer-based simulations, in particular, have provided manufacturers with a means to create virtual representations of their systems, allowing them to test and optimize different scenarios without implementing physical changes. Such tools include discrete event simulation, finite element analysis, and Monte Carlo simulations, among others.

### SUMMARY

Example embodiments include a computer-implemented method of evaluating operation of a manufacturing system. A resource graph may be obtained, defining 1) a plurality of resource nodes each representing a physical resource of a plurality of physical resources of the manufacturing system, and 2) a plurality of resource links each representing a causal dependency between at least two of the resource nodes. A process graph may be obtained, defining 1) a plurality of service nodes each representing a service of a plurality of services performed by the manufacturing system, and 2) a plurality of service links each representing a causal dependency between at least two of the service nodes. A mapping may also be obtained, defining a map between the service links and the resource nodes, the mapping representing use of the physical resources by the services. Performance metrics of the manufacturing system may be modeled by simulating performance of the plurality of services as a function of the resource graph and the process graph under plural sets of operational parameters. The modeling may include 1) determining a change in status of the resource nodes over a runtime as a function of operation of the service nodes, and 2) determining a change in the operation of the service nodes over the runtime as a function of the change in status of the resource nodes.

A risk may be identified based on the modeled performance metrics, the risk indicating a change in the performance metrics that exceeds a predetermined threshold. At least one of the plural sets of operational parameters associated with an outcome absent the risk may then be identified. A modification to the manufacturing system may be determined based on the operational parameters associated with the outcome absent the risk. The resource graph and/or the process graph may then be updated based on the modification.

The plurality of services may include generating a product, processing a product, and transporting a product. The plurality of resource links may represent a relationship between an operational capacity of two or more of the resource nodes. The plurality of service links may represent a relationship between an input and an output of two or more of the service nodes. The mapping may include 1) an association between one resource node and multiple service nodes, and 2) an association between one service node and multiple resource nodes. The plural sets of operational parameters may be distinct from one another by defining at least one of: failure of a resource node, a delay of a service, a modification to the service links indicating a different sequence of operations, and a modification to the service links indicating an alternative mode of operation.

The plurality of resource nodes may each include a respective emission parameter, the emission parameter indicating a rate of pollutant emission caused by the respective physical resource, and an environmental impact may be identified based on the modeled performance metrics and the respective emission parameters. At least one of the plural sets of operational parameters associated with a reduced environmental impact may be identified, and a modification to the manufacturing system based on the operational parameters associated with the reduced environmental impact.

The plurality of service nodes may each define a subset of the runtime in which the respective service is active and a subset of the runtime in which the respective service is inactive. The plurality of resource nodes may each define a capacity to perform at least one of the plurality of services during a given time period.

Variation of the risk under the plural sets of operational parameters may be identified, and a function relating the performance metrics and the risk based on the variation may be determined. The performance metrics may include a sustainability metric indicating repeatability of a manufacturing process over time, as well as an energy metric indicating an availability of energy to perform the plurality of services in excess of energy consumed by the manufacturing system. The manufacturing system may be updated to incorporate the modification.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a block diagram illustrating generation of a manufacturing system model in one embodiment.

FIG. 2 is a flow diagram of a process of configuring and operating a manufacturing system model in one embodiment.

FIG. 3 is a diagram of a map relating parameters and outcomes in one embodiment.

FIG. 4 is a flow diagram of a process of determining a diagnosis and remedy in one embodiment.

FIG. 5 is a diagram illustrating a lookup table cross-referencing manufacturing system states, risks, and corresponding remedies in one embodiment.

FIG. 6 is a flow diagram illustrating a process of deconstruction, emulation and analysis of a manufacturing system's performance accounting for dynamic complexity.

FIG. 7 is a flow diagram illustrating a process of emulating a manufacturing system's performance under varying parameters accounting for dynamic complexity.

FIG. 8 is a flow diagram illustrating a process for determining whether an adverse outcome has occurred.

FIG. 9 is a flow diagram illustrating a process for diagnosing a manufacturing system following detection of an adverse outcome.

FIG. 10 is a state diagram illustrating a process for manufacturing system risk management in one embodiment.

FIG. 11 is a diagram of a portion of a dependency graph of a manufacturing system model, illustrating propagation of a risk, in one embodiment.

FIG. 12 illustrates a computer network or similar digital processing environment in which embodiments of the present invention may be implemented.

FIG. 13 is a diagram of an example internal structure of a computer (e.g., client processor/device or server computers) in the computer system of FIG. 12.

FIG. 14 is a table representing a resource node in one embodiment.

FIG. 15 is a graph illustrating an output of an example embodiment projecting production yield versus demand intensity.

FIG. 16 is high-level service graph in one embodiment.

FIG. 17 illustrates a process graph in one embodiment.

FIG. 18 shows a resource graph in one embodiment.

### DETAILED DESCRIPTION

A description of example embodiments follows.

Modern businesses are primarily defined by their translation into systems, whether it be a product, supply chain, production line, or any other set of interacting or interdependent components. These systems include millions upon millions of components, dynamic interactions and interdependencies that combine to achieve the overall objectives set forth by business stakeholders. Due to interdependencies, time constraints, and feedback loops, any changes may disrupt manufacturing processes in unanticipated ways. For example, a pandemic can cause supply chain disruptions or labor shortages, while economic turmoil can change a company's financial position overnight.

Avoiding the overall breakdown of production processes, which can be caused by strains on any interconnected internal or external systems, is an ongoing challenge for manufacturers. At the same time, manufacturing design, engineering, assembly, and services can quickly become obsolete due to innovations, changing regulations, or shifts in consumer demand.

To thrive in this new environment, manufacturers must constantly respond to change and optimize their approach across all levels. In many applications, it is no longer feasible to reactively manage the dynamics of Industry 4.0. The now predominant crisis management mode of operations should be replaced with more adaptable business practices that support a higher standard of excellence. The ability to anticipate problems and proactively seize opportunities needs to be woven into the fabric of business. Example embodiments, described below, provide manufacturers with the metrics and insights they need to deal with modern business dynamics, which have become too complex to manage using current state-of-the-art decision support tools.

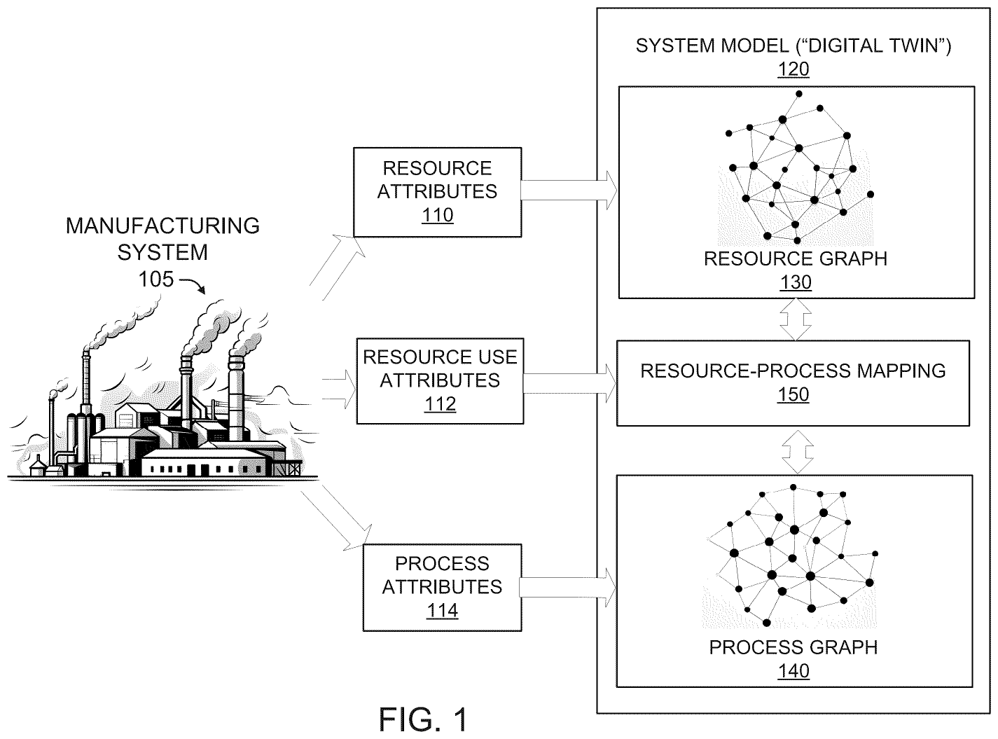

FIG. 1 is a block diagram illustrating generation of a manufacturing system model 120, also referred to as a Digital Twin (DT), in one embodiment. The manufacturing system model 120 may be generated from various attributes and data collected from a real-world manufacturing system 105, including process attributes 110, resource use attributes 112, and process attributes 114. The resource attributes 110 may be collected through analysis of the physical resources making up the manufacturing system 105, including manufacturing equipment, transportation vehicles, and human resources. The resource attributes 110 may also identify dependencies between resources, such as a manufacturing station that is dependent on various sub-components to function. Similarly, the process attributes 114 may be collected by analyzing the processes performed by the system 105, which may be organized into a hierarchy of processes. For example, the process attributes 114 may identify larger processes (e.g., manufacturing a given product) and smaller processes on which the larger processes depend (e.g., manufacturing a component of the given product). Lastly, the resource use attributes 112 identify the physical resources used by each of the processes, referencing both the entries of the resource attributes 110 and the process attributes 114.

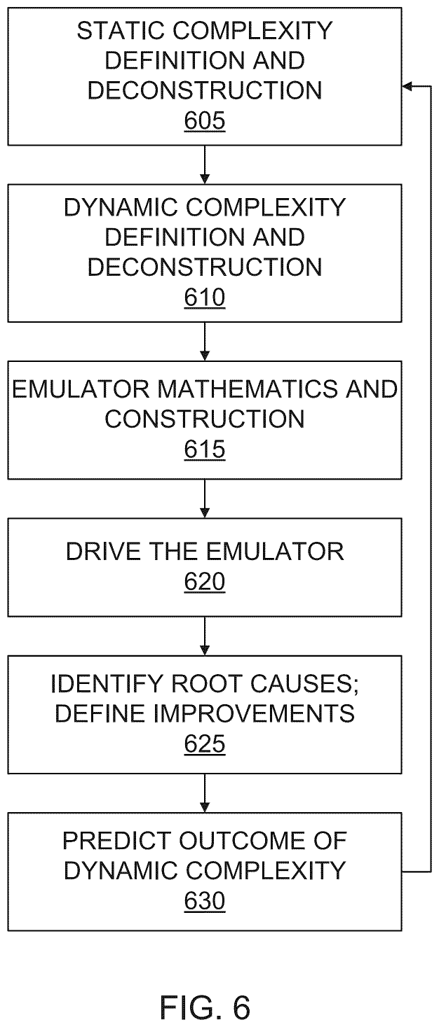

Once collected, the attributes 110, 112, 114 of the manufacturing system 105 may be processed to generate the components of the system model 120. The system model 120 may be constructed according to the process described below with reference to FIG. 6, and so may incorporate definitions of both static and dynamic complexity. Further, the system model 120 may be structured as a plurality of dependency graphs and mappings, described in further detail below, representing the attributes 110, 112, 114. In particular, the system model 120 may include a resource graph 140 that represents the resource attributes 110, a process graph 140 that represents the process attributes 114, and a resource-process mapping 150 that represents the resource use attributes 112. The resource graph 130 may define a plurality of resource nodes each representing a respective physical resource of the manufacturing system 105. The resource nodes may be linked by a plurality of resource links each representing a causal dependency between two or more of the resource nodes. Further, the resource links may define a relationship between an operational capacity of two or more of the resource nodes. For example, such a resource link may define a dependency of one resource (e.g., an assembly robot) on another resource (e.g., a power supply), or a dependency of multiple resources (e.g., a series of assembly robots) on another resource (e.g., a conveyor belt). The resource graph 130 may also represent the environmental impact of operating the various resources of the manufacturing system 105. For example, some or all of the resource nodes may each include a respective emission parameter, which may indicate a rate of pollutant emission (e.g., carbon dioxide) caused by the respective physical resource. As a result, an environmental impact can be identified based on the modeled performance metrics of the system model 120 and the respective emission parameters.

Similarly, the process graph 140 may define a plurality of service nodes each representing a respective service performed by the manufacturing system 105. For example, services represented by the nodes may include generating a product, processing a product, and transporting a product. The service nodes may also define a subset of the manufacturing system runtime in which the respective service is active and a subset of the runtime in which the respective service is inactive. Such a configuration may be in correspondence with the resource nodes, which may each define a capacity to perform one or more of the services during a given time period. The service nodes may be linked by service links each representing a causal dependency between two or more of the service nodes. In particular, the service links may represent a relationship between an input and an output of two or more of the service nodes, such as the relation between successive stations of a manufacturing assembly line.

The resource-process mapping 150 may define a map between the service links and the resource nodes, representing use of the physical resources by the services. The mapping may represent one-to-many and many-to-many relations between services and resources. For example, the mapping may define an association between one resource node and multiple service nodes, and/or an association between one service node and multiple resource nodes.

Thus, the manufacturing system model 120 may represent the manufacturing system 105 by incorporating the resource attributes 110, resource use attributes 112, and process attributes 114 into the interconnected resource graph 130, resource-process mapping 150, and process graph 140, respectively. The manufacturing system model 120 may be configured to represent the manufacturing system 105 at a given point in time (e.g., when the attributes 110, 112, 114 are collected), and may be updated as newer attributes are collected from the manufacturing system 105.

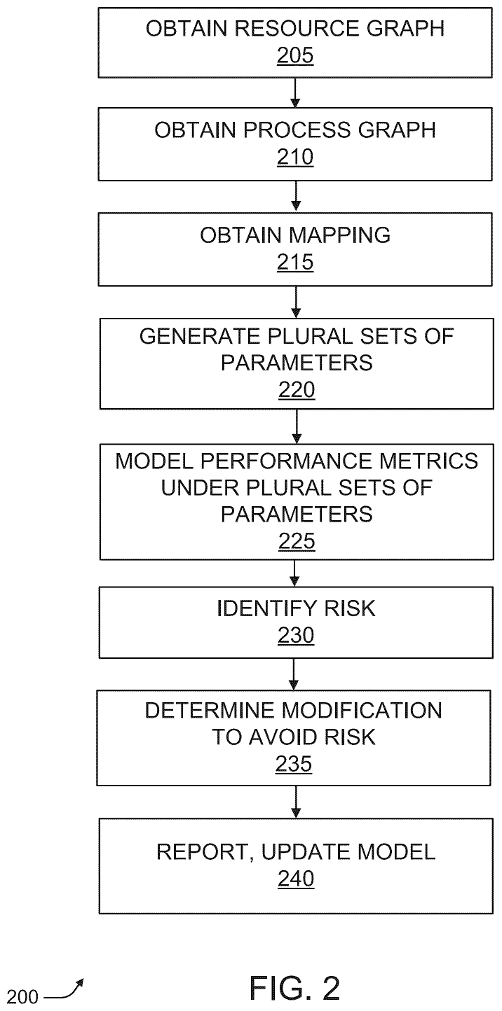

FIG. 2 is a flow diagram of a computer-implemented process 200 of configuring and operating a manufacturing system model, such as the model 120 described above. The process 200 may incorporate features of the processes for emulating a manufacturing system and identifying adverse outcomes as described below with reference to FIGS. 6-10. Further, the process 200 may be incorporated into the process described below with reference to FIG. 6, and in particular expands upon the features of driving an emulator and identifying root causes and defining improvements.

With reference to FIG. 1, initially, the resource graph 130, resource-process mapping 150, and process graph 140 may be obtained from a process such as described above (205, 210, 215). The system model 120 may be constructed from these graphs/mappings according to the process described below with reference to FIG. 6, and so may incorporate definitions of independency and static and dynamic complexity.

Once the manufacturing system model 120 is complete, it may be modeled (simulated) under plural sets of parameters. The plural sets of parameters may be previously generated as detailed with reference to the example embodiments described below (220), and each of the plural sets of parameters may indicate respective variables having a causal relation to the performance metrics. For example, the plural sets of operational parameters may be distinct from one another by defining a failure of a resource node, a delay of a service, a modification to the service links indicating a different sequence of operations, and/or a modification to the service links indicating an alternative mode of operation.

The operation of the manufacturing system model 120 is then modeled under the plural sets of parameters to generate respective performance metrics (e.g., sustainability metrics, environmental impact metrics) (225). Performance metrics of the manufacturing system 105 may be modeled by simulating performance of the plurality of services as a function of the resource graph 130 and the process graph 140 under plural sets of operational parameters. The modeling may include, for example, determining a change in status of the resource nodes over a runtime as a function of operation of the service nodes, and determining a change in the operation of the service nodes over the runtime as a function of the change in status of the resource nodes. The performance metrics may include a sustainability metric indicating repeatability of a manufacturing process over time, as well as an energy metric representing an availability of energy to perform the plurality of services in excess of energy consumed by the manufacturing system 105.

From an analysis of the plural sets of parameters and the resulting performance metrics, occurrence probabilities for each of the sets of parameters can be determined to identify risks to the system (230). The occurrence probabilities may indicate predicted probabilities of the manufacturing system model transitioning from an initial state to each of a plurality of successive states, each of the successive states corresponding to a respective one of the plural sets of parameters. Some of those successive states may be identified to relate to an adverse outcome, such as a failure state representing the manufacturing system 105 being unable to continue operations, or an outcome wherein the manufacturing system's performance metrics decrease below a given threshold. Accordingly, one or more risks may also be identified, wherein the risks indicate a likelihood of the manufacturing system 105 (represented by the model 120) transitioning from the initial state (corresponding to the initial state at which the attributes were collected) to an adverse outcome such as a system failure. The risk may indicate a change in the performance metrics that exceeds a predetermined threshold of change, or a predetermined threshold rate of change, over time. Further, variation of the risk under the plural sets of operational parameters may be identified, and a function relating the performance metrics and the risk based on the variation may be determined.

Further, the analysis of the plural sets of parameters and the resulting performance metrics can identify parameters that result in outcomes that are absent the risk. Those sets of parameters can include, for example, a difference in resources and/or processes compared to the initial system state. Thus, by modifying the system in the manner indicated by those identified parameters may result in avoiding a given risk. Accordingly, one or more modifications to the manufacturing system may be determined based on the operational parameters associated with the outcome absent the risk (235). Such analysis can also assess an environmental impact of the manufacturing system 105. For example, one or more of the plural sets of operational parameters associated with a reduced environmental impact may be identified, and a modification to the manufacturing system based on the operational parameters associated with the reduced environmental impact.

Based on the findings of risk and risk avoidance, a report may be generated for the manufacturing system 105 (240). The report may indicate the identified risks, and may also provide a diagnosis of the manufacturing system 105 and one or more modifications that are predicted, based on the plural sets of parameters and resulting performance metrics, to avoid or prevent an adverse outcome. Example processes for determine such diagnoses and remedies are described in further detail below. The manufacturing system 105 can then be updated to incorporate one or more of the identified modifications, thereby improving the system 105 in accordance with the identified goals, such as sustainable operation over time and/or minimal environmental impact. The resource graph 130 and/or the process graph 140 may also be updated based on the modification.

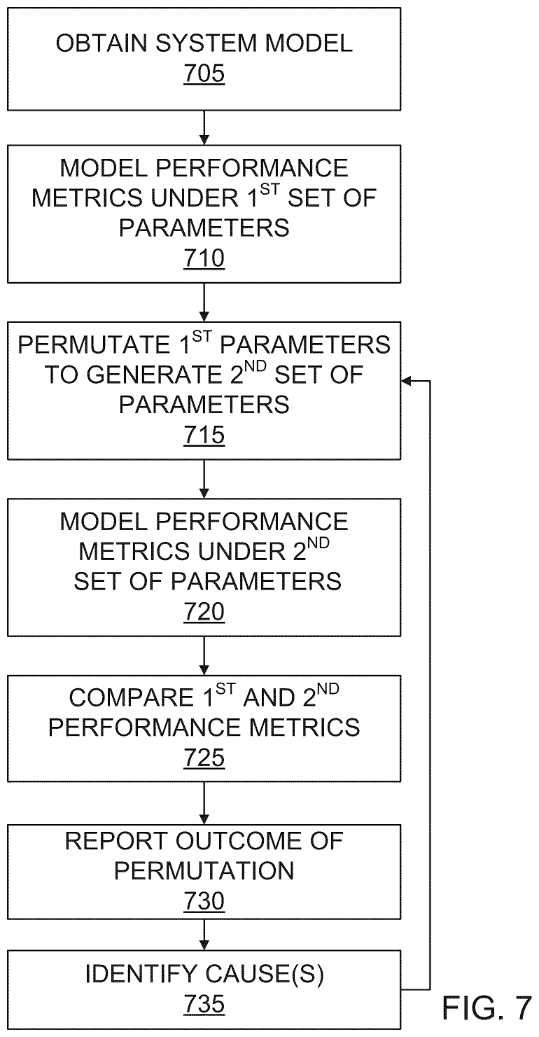

Example embodiments, as described herein, provide for emulating a manufacturing system model 120 through a number of differing scenarios, where the results of such emulations can be analyzed to identify operational concerns and potential remedies and optimizations for the manufacturing system 105. One aspect of this emulation, as described above, is to generate plural sets of parameters (220). In order to generate those sets of parameters, a set of input parameters may be permutated, by altering one or more values, to generate one or more additional scenarios for emulation. Such selection of differing parameters is described herein, and in particular with reference to FIG. 7. When selecting input parameters to detect an adverse outcome resulting from a manufacturing system model's dynamic complexity, a number of variables can be selected for permutation. For example, input parameters can be permutated to simulate the manufacturing system under different configurations or constraints of resources and/or different service demands. Further, the length of time over which the model 120 is emulated may be varied, and this variation may be managed by an AI process based on the outcomes to be investigated. Such variation in time may be employed, with or without other permutations, to determine whether the input parameters result in an adverse outcome over a different (e.g., longer) length of time.

In an example embodiment, a first of the sets of parameters may correspond to an initial state of the manufacturing system 105 (e.g., corresponding to measured attributes at an initial point in time), or may correspond to a hypothetical or predicted state of the manufacturing system 105. Further, additional instances of the sets of parameters may correspond to a range of permutations of the first set of parameters, which may correspond to deviations from the initial state of the manufacturing system. Such deviations can include the permutations described above.

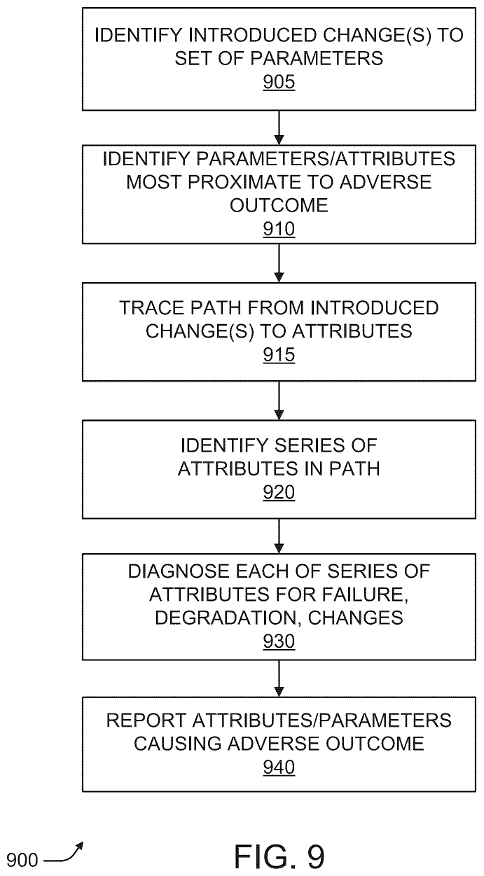

With the sets of parameters defined, the model may then be simulated under each of the sets of parameters to generate corresponding sets of performance metrics (225). The sets of performance metrics may also include a dimension of time (referred to, for example, as time “T1”), indicating that the results correspond to the first set of input parameters upon simulation for a given length of (simulated) time. Following obtaining resulting performance metrics, those metrics may be analyzed, as described above with reference to FIGS. 7-9, to identify one or more adverse outcomes. The performance metrics can be analyzed further, as described below with reference to FIG. 9, to identify the cause or causes of the modeled results. The steps of simulation and analysis (220-230) may be repeated, with further permutations, to determine performance (e.g., a new set of performance metrics and risk estimation) and identify adverse outcomes under a range of scenarios corresponding to different input parameters.

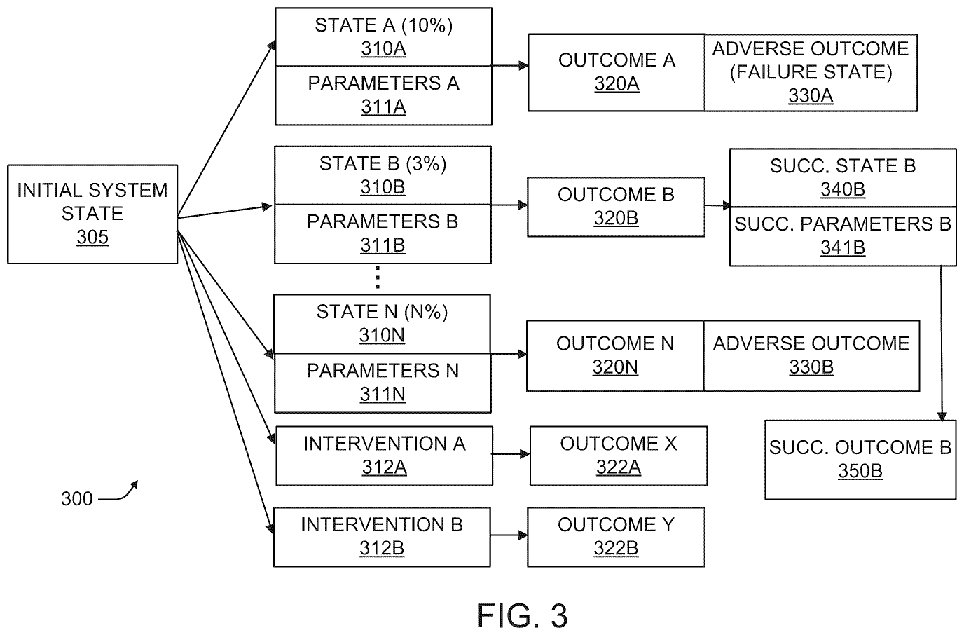

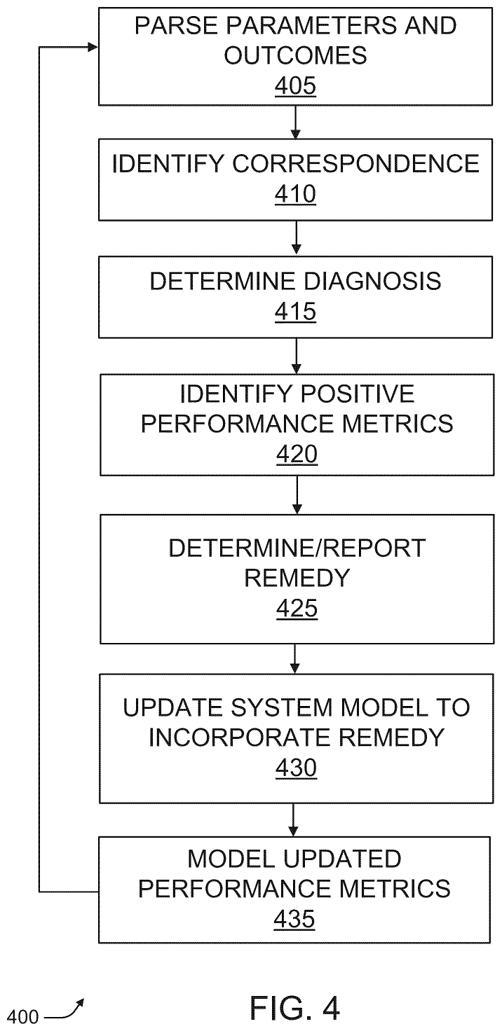

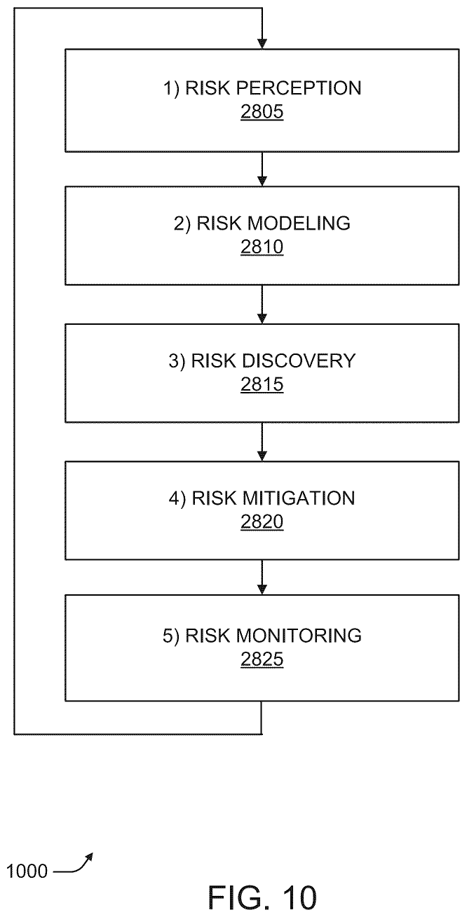

Given the identified adverse outcome(s), a map can be generated to relate the adverse outcome(s) to corresponding instances of the plural sets of parameters. An example map is described below with reference to FIG. 3. Based on this map, one or more risks can be determined and reported, where the risk(s) define a probability of an outcome including an adverse outcome. In particular, the risk may be calculated based on the occurrence probability of each of the instances of the plural sets of parameters that are related to the identified adverse outcomes. The risks may then be reported to a user in a manner comparable to the reporting as described above (235), and may be provided for further analysis as described in further detail below with reference to FIGS. 4 and 10. Reports can include a metric representing risk (e.g., risk index).

FIG. 3 is a diagram of a map 300 relating parameters and outcomes in one embodiment. The map 300 may be generated as a result of the process 200 described above with reference to FIG. 2, and connects an initial manufacturing system model state 305 to a range of successive manufacturing system states 310A-N each having a respective set of parameters 311A-N, which in turn are related to corresponding outcomes 320A-N and, where applicable, corresponding adverse outcomes 330A-B. The adverse outcomes 110A-B can include a failure state (e.g., 330A) indicating that the manufacturing system model exhibits a system-wide failure, and/or other negative or potentially harmful results, such as performance metrics that exceed a given threshold or updated performance attributes that indicate a decline in performance. In addition to the successive states 310A-N, the map 300 may also account for interventions 312A-B. The interventions 312A-B may be comparable to the state/parameter pairs in that they represent a respective set of parameters and a resulting state representing the manufacturing system model 120. However, the interventions 312A-B, along with their respective outcomes 322A-B, are shown separately to highlight the range of scenarios that may be simulated in example embodiments. The interventions 312A-B, in particular, may indicate parameters that represent scenarios in which one or more positive modifications are made to the manufacturing system model 120, such as adding resources, redirecting or reorganizing resources, and modifying services for greater efficiency or sustainability. The intervention 312A may be proposed and simulated after one or more prior simulations (e.g., under parameters 311A-N) are found to indicate a risk of the manufacturing system failing to meet the service output required by the corresponding parameters.

The parameters 311A-N may correspond to each of the scenarios modeled as described above, and the outcomes 320A-N may include corresponding performance metrics resulting from the modeling. Further, if an adverse outcome (e.g., system failure 110A) is identified from modeling the manufacturing system model under a given set of parameters, the adverse outcome is associated with the outcome (e.g., outcome 320A), thereby “flagging” the outcome. Over a range of different (e.g., permutated) parameters 310A-N, some of the corresponding outcomes 320A-N may be associated with adverse outcomes 110A-B, while others may not. In an alternative embodiment, a map may be generated to include only outcomes that are associated with adverse outcomes.

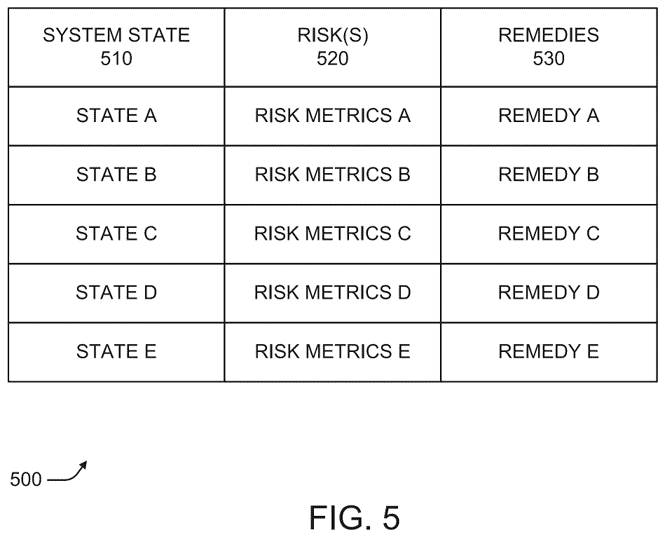

From the map 300, one or more risks to the manufacturing system model can be determined. A risk, as described above, may indicate a probability that the manufacturing system model will encounter an outcome that includes an adverse outcome such as a system failure. Such risks can be calculated through a number of means and may be expressed in a number of different ways, and examples of such analysis and presentation are provided in further detail below. In one example, an occurrence probability may be assigned to each of the successive states 310A-310N, where the occurrence probability indicates a likelihood that the manufacturing system model will move from the initial state 305 to a state having the given parameters. For example, the state 310A is assigned an occurrence probability of 10%, indicating that the manufacturing system model has a 10% chance of transitioning to the state 310A, under which the manufacturing system model is simulated under the corresponding parameters 311A. Such an occurrence probability may be determined based on historical data about the manufacturing system model, industry data, historical simulation data, data about comparable manufacturing system models, the manufacturing system's performance attributes, and/or other sources. Based on the occurrence probability of each of the states 310A-N, one or more risks (e.g., the probability of an outcome including one or more of the adverse outcomes 110A-B) can be determined. The risks may be reported to a user, including details of the predicted adverse outcomes and the likelihood of each. The risks may also be further processed, for example, to generate a lookup table, an example of which is described below with reference to FIG. 5.

As shown, the map 300 may depict two points in time: the initial manufacturing system state 305 representing the manufacturing system at an initial point in time (T1), and the successive manufacturing system states 310A-N (and interventions 312A-B) representing the potential outcomes for a manufacturing system at a later point in time (T2). Although the successive states 310A-N may represent different potential outcomes at a common point in time, they may instead represent different points in time. For example, state 310A may represent at an earlier simulated point in time than state 310B because the simulation reveals that the state 310A results in the adverse outcome 110A, and as such, the modeling of the state 310A may be terminated earlier, while state 310B may be simulated for longer to ensure that the outcome 320B does not include an adverse outcome.

Further, any of the simulated scenarios involving the successive states 310A-N (and/or interventions 312A-B) may be extended beyond those successive states to predict a state and outcome of the manufacturing system model at a still later point in time (T3). For example, as shown in FIG. 3, state 310B results in the performance metrics of outcome 320B at time T2. Those performance metrics, in turn, may be applied to the manufacturing system model, and the manufacturing system model may then be modeled under successive state 340B with successive parameters 341B, which may be the same or different from parameters 311B. As a result, a successive outcome 350B, indicating a predicted state of the manufacturing system model at time T3 in response to imposing the successive parameters 341B, may be determined. Alternatively, for successive simulations, any of the successive states 310A-N (or interventions 312A-N) may be implemented in place of the initial manufacturing system state 305, meaning that the manufacturing system model may be configured with performance attributes based on the performance metrics indicated by the outcome associated with the successive state. For example, state 310B may be configured as a new initial state with performance attributes in accordance with outcome 320, and the manufacturing system model may be simulated under transitions to the plurality of successive states 310A-N, producing corresponding outcomes and indications of risk of adverse outcomes. Thus, the manufacturing system model can be simulated under one or more series of successive scenarios, which can provide 1) a predicted outcome that is responsive to multiple changes to the manufacturing system model (e.g., performance attributes, performance metrics, interventions) over time, and/or 2) a branching series of scenarios, originating from a single initial manufacturing system state, that accounts for several sets of parameters and predicts a range of potential outcomes for each scenario following multiple changes to the manufacturing system model.

FIG. 4 is a flow diagram of a process 400 of determining a diagnosis and remedy in one embodiment. The process 400 may be operated in conjunction with the process 200 described above to further investigate the causes of negative outcomes, such as a decline in performance metrics, altered performance attributes, or an increased risk of an adverse outcome such as a system failure. The process 400 may also identify effective remedies/interventions by identifying a causal relation between those remedies/interventions and an improvement to the outcome of the manufacturing system model under the modeled scenarios.

As described above, the operating the manufacturing system model through plural sets of parameters may yield a set of results, including performance metrics, positive and negative outcomes, risks of adverse outcomes, and, potentially, changes to the performance attributes of the manufacturing system model in subsequent scenarios. Those results may be used to generate a map 300 as shown in FIG. 3, which relates an initial manufacturing system state, subsequent states (by occurrence probability of a range of parameters), outcomes, and risks of adverse outcomes. Utilizing the map 300 or another data format, those results may be parsed (405) to identify correspondence between a subset of the performance attributes, the plural performance metric results, and the risk (410). This action may implement some or all of the process 900 described below with reference to FIG. 9. Based on this correspondence, a manufacturing system diagnosis can be determined, wherein the manufacturing system diagnosis may indicate the subset of performance attributes that exceed a threshold correspondence with the risk (415).

Following diagnosis or as a separate process, one or more remedies can be determined. The remedies may correspond to one or more modifications to the manufacturing system model (e.g., performance attributes) that have a causal relation to one or more positive changes to the manufacturing system model, such as changes that reduce or avoid a risk of an adverse outcome (e.g., a system failure), or a positive change in the manufacturing system model's performance metrics or performance attributes in subsequent modeling. The process of identifying such remedies may implement features of the process 900 described below, except that the targets to be identified are performance attributes and/or sets of parameters (e.g., positive interventions) that are responsible for a positive change in the manufacturing system model and/or performance metrics (420). For example, a modeled scenario under a given set of parameters (e.g., an intervention) may result in positive performance metrics for the manufacturing system model. Through multiple simulations and analysis, one or more parameters of the set of parameters may be identified as having a causal relation with the positive performance metrics. Accordingly, a remedy can be determined as a change to the manufacturing system model in accordance with the one or more parameters, and that remedy may then be reported to a user (425). In a further example, a subset of the performance metrics that are negatively correlated with an adverse outcome (e.g., system failure) is identified, and a remedy can be identified as one or more of the respective variables (e.g., of a set of parameters) that are associated with the subset of performance metrics. In a still further example, determining the remedy may include 1) generating an additional set of parameters, the additional set of parameters indicating a performance intervention; 2) modeling the performance metrics of the manufacturing system model under the additional set of parameters to generate a performance metric result; and 3) identifying the remedy based on the performance metrics associated with the performance intervention.

Optionally, the remedy may be incorporated into a reference table such as the table 500 described below with reference to FIG. 5. The manufacturing system 105 may then be modified in accordance with the remedy, for example by expanding, reorganizing, or redirecting the resources and/or services of the system 105. Optionally, the manufacturing system model 120 may be updated to incorporate the remedy, for example by updating the attributes 110, 112, 114 or the graphs 130, 140 or mapping 150 in accordance with the remedy (430). The manufacturing system model may then be simulated under the same or the additional sets of parameters to determine updated performance metrics, thereby testing and/or validating the efficacy of the remedy (435).

FIG. 5 is a diagram illustrating a lookup table 500 cross-referencing manufacturing system model states 510, risks 520, and corresponding remedies 530 in one embodiment. The table 500 may be generated based on the information resulting from the process 200 of identifying risks as described above with reference to FIG. 2. In particular, the manufacturing system model states 510 may be populated from a number of different iterations of the manufacturing system model, each of which may have been modeled under a range of permutated parameters. Likewise, the risk metrics 520 indicate, for each of the manufacturing system model states 510, the risks associated with the given state. The remedies 530 may be populated by actions and/or modifications to the manufacturing system model and/or external resources that are effective in preventing or avoiding adverse outcomes associated with a given risk. Such remedies 530 may be determined by the methods described herein. For example, the manufacturing system model may be modeled under parameters that include a prospective remedy, and, if the prospective remedy is determined to mitigate or avoid a predicted adverse outcome, then the prospective remedy may be included in the table 500 as a solution to a corresponding risk.

The lookup table 500 may be accessed using information on a given state of the information manufacturing system model. For example, for diagnostic applications, the state of the manufacturing system model may be analyzed and then compared to entries in the lookup table to determine the risk inherent in the manufacturing system model. The remedies 530, including remedies and/or suggested actions (e.g., modifications to the manufacturing system model) to avoid the risk(s), can also be reported, such that they may be implemented by the manufacturing system model itself.

FIG. 6 is a flow diagram illustrating a process of deconstruction, emulation and analysis of a manufacturing system's performance accounting for dynamic complexity. The process includes stages that are described above, in particular with reference to FIGS. 1-5, where a subject manufacturing system model or environment is defined in terms of static complexity (i.e., the layering architecture and characteristics of each component in the manufacturing system model), the manufacturing system model is modeled and emulated under varying conditions, and the results of the emulation are analyzed and quantified, providing for solutions for improving the manufacturing system model. The process further includes defining the subject manufacturing system model in terms of dynamic complexity, and those definitions are incorporated into the stages of modeling, emulation and analysis.

The stages, as shown in FIG. 6, include: 1) Definition of the static complexity base and its deconstruction (605), 2) Definition of the dynamic complexity base and its deconstruction (610), 3) Construction of the emulator based upon defined Mathematics and Deconstruction (615), 4) Drive the emulator (620), 5) Identify root causes of unexpected behavior/adverse outcomes and define improvements (625), and 6) Predict the new behavior patterns with the dynamic complexity (as newly defined at 610) using the emulator (630). Each stage follows the previous stage such that the outputs of one stage become the inputs of the next stage. Each stage is described in further detail below.

### Stage 1: Definition of the Static Complexity Base and its Deconstruction (605)

As an initial stage of preparing a mathematical model of a subject manufacturing system model and environment, information is collected regarding each of the components of the subject manufacturing system model, as well as the operational connections between those components. The information to be collected is sufficient for drawing an accurate mathematical model as described above with reference to FIGS. 1-5, and an example process of such information collection can be found in U.S. Pat. No. 6,311,144 (herein incorporated by reference). Inputs of this stage (605) include information regarding the manufacturing system (e.g., performance attributes) and construct of the environment and manufacturing system model that are its static definition, including functional definitions (how each component of the manufacturing system model operates and interacts with other components) and physical definitions (layered architecture). The output of this stage (605) is a definition of the static complexity base of the subject environment or manufacturing system model.

In order to achieve an accurate static deconstruction of the subject manufacturing system model, the following actions may be taken:
1. Discover and identify the units or parts that make-up the environment or manufacturing system model. The granularity of this identification will vary with degree of precision that is needed to make the predictions at a later stage.
2. Discover and identify how these units are interconnected.
3. Discover and identify what flows along these connections.

### Stage 2: Definition of the Dynamic Complexity Base and its Deconstruction (610)

In order to characterize a model of the manufacturing system model beyond its static description, additional information about the subject manufacturing system model and its components is collected and incorporated into the model as a definition of the dynamic complexity of the manufacturing system model. Inputs of this stage include the static complexity definition produced in stage (605), as well as information regarding how the static complexity changes over time. This information can be obtained through analysis of historical data about the manufacturing system model, epidemiological data (e.g., data derived from a given population that relates performance attributes and incidences of various changes exhibited by the population), historical simulation data, data about comparable manufacturing system models, the manufacturing system's performance attributes, and/or other sources. The output of this stage (610) is a definition of the dynamic complexity base model of the manufacturing system model. In order to achieve an accurate dynamic deconstruction of a manufacturing system model, the following actions may be taken:
1. Discover and identify how each part or unit might change within the static complexity definition, which in turn indicates dynamic complexity.
2. Discover and identify how the connections within the static complexity base model have changed.

### Stage 3: Construction of an Emulator Based upon Defined Mathematics Deconstruction (615)

Given the static and dynamic definitions of the subject manufacturing system model (605, 610), a mathematical model of the subject manufacturing system model is then constructed for emulation (615). The mathematical model may be constructed as described above with reference to FIGS. 1-5, and may follow approaches as described in U.S. Pat. No. 6,311,144 (incorporated herein by reference). Inputs of this stage include the dynamic complexity definition produced in stage (610), defined mathematical techniques for emulation of the model, and computer programming techniques for production of the model. Outputs of this stage (615) include the emulator that can be used to establish the dynamic complexity and the resulting behavior patterns of the defined environment or manufacturing system model.

The mathematics of the emulator may include the following definitions:

U.S. Pat. No. 7,389,211 establishes the basis for a mathematical predictive solution that analytically predict system performance (in general terms). According to one embodiment such solution can be conceptually expressed in the form:

X=X₀+Σ_{M}^{(d)}X_{M}+Σ_{N}^{(s)}X_{N} (1)
Where X₀ is the initial value of a metric domain (e.g. complexity impact on performance, cost, capacity etc.)
X_{N} is calculated direct impact due to N causes of static complexity (number of connections, number of interfaces, number of links, number of sites, distances, etc.)
X_{M} is calculated direct impact due to M causes of dynamic complexity (interaction that impact components effectiveness, feedback that require higher throughput, interferences that impact liquidity, pandemic that impact health, aging that impact longevity etc.)

Convolution theorem allows a solution of a combined mathematical expression of two function-domains:

$$X = \frac{δ X}{δ σ} and {σ}^{′} = \frac{d σ}{dt}$$

with the combined solution using Laplace Transform [symbol] :

Complexity Function h(σ)= [symbol] ∫X(τ)·σ(t−τ)dτ (2)

Let us denote the vector σ=σ(k) that represent the set of metrics that define a domain The system of equations that represents the variations is:

$$\frac{d σ}{dt} = {X}^{( d )} ( {σ}^{( d )} ) + {X}^{( s )} ( {σ}^{( s )} ) \qquad ( 3 )$$

From (1) and (2) the impact of complexity on the domain metrics and using Laplace transform, is:

$$\frac{d σ}{dt} = {\sum }_{k}^{( d )} \frac{d {X}_{d}}{d {σ}_{k}} 〈 {σ}^{′ ( d )} , {σ}^{″ ( d )} 〉 + {\sum }_{k}^{( s )} \frac{a {X}_{s}}{d {σ}_{k}} \{ {σ}^{{′ ( s )}_{}} , {σ}^{″ ( s )} \} \qquad ( 4 )$$

d and s denote the 2 types of complexities and,

$$\frac{d {X}_{d}}{d {σ}_{z}} and \frac{{dX}_{s}}{d {σ}_{k}}$$

are computed by the method proposed in NA(3) where (σ′^{(d)},σ″^{(d)}) and ((σ′^{(s)},σ″^{(s)}) are representing σ through different coordinates and σ^{i,s or d} represent the complexity (i order) derivative, expressed in exponential form

σ′⁽ⁱ⁾=Σₖ⁽ⁱ⁾Σₙ⁽ⁱ⁾C_{n,k} ex^{zt} (5)

where z is a complex variable that represent the two complexities z=σ^{(s)}+iσ^{(d)} where i=\sqrt{−1}, σ^{(s)}) and σ^{(d)}) the static and dynamic complexity respectively

The set of equations 3, 4 and 5 allow the computation of all domain metrics as a function of varying the two portions of complexity representation.

We propose an aggregative concept, let us call it Complexial that represents the aggregated impact produced in each domain X₀ of the vector X₀ where X₀ (1) is performance, X₀ (2) denotes cost, X₀ (3) means quality of service and X₀ (4) represents availability etc.

From the above:

Complexial=ξ=Πₙ(X₀(n)+X′(n)+X″(n)+. . . ) where Xⁱ are the complexity contribution of higher order perturbations (direct and indirect) of domain metrics n.

### Stage 4 Drive the Emulator (620)

Once the mathematical model of the subject manufacturing system model or environment has been defined, the model is then emulated. The mathematical model may be constructed as described above, and may implement approaches as described in U.S. Pat. No. 6,311,144 (herein incorporated by reference). Inputs of this stage (620) include the mathematical model (emulator) from the previous stage (615), as well as one or more sets of operational scenarios that will be the actions that drive the emulation of the subject environment or manufacturing system model. Outputs of this stage (620) include a set of reactions of the emulated manufacturing system model that shows its behavior under a set of varying scenarios and how its complexity changes, as well as conditions and points in time when the behavior of the environment or manufacturing system model becomes singular or encounters another adverse or unacceptable outcome.

The outputs of this stage (620) allow for discovery and identity of when the behavior of the emulated environment or manufacturing system model becomes ‘unexpected’ due to a sudden change. This may comprise running a number of starting positions and controlling the emulator to run for a number of different time lines under different initial conditions.

In short, to establish a “manufacturing system model limit” due to complexity, two results in particular are identified. First, the manufacturing system model limit due to static complexity (the “ceiling”) is what may be deemed to be the predictable limit that we understand from simple extrapolations, statistical trending and actual experiences. The “ceiling” is what is normally understood as the operational limits of a manufacturing system model. Second, the manufacturing system model limit due to dynamic complexity (a singularity), which is unpredictable by conventional methods (e.g. statistical trending) is identified. A singularity may occur at any point in time, predictable and governable through the mathematical methods that emulate interactions, feedback and interferences provided in example embodiments.

### Stage 5: Identify Root Causes of Unexpected Behavior/Adverse Outcomes and Define Improvements (625)

Once the mathematical model has been emulated through one or more test scenarios as described above, the results of the emulation can be analyzed to identify the root causes of the various detected results, including adverse outcomes (e.g., a system failure), and changes to the manufacturing system model (e.g., remedies) to avoid such adverse outcomes. Inputs at this stage (625) include the calculated results of emulation from the previous stage (620), as well as measurements and observations of the actual manufacturing system model to condition and verify the outputs of the previous stage (620). Outputs of this stage (625) include remedies, which are suggested changes to the manufacturing system model.

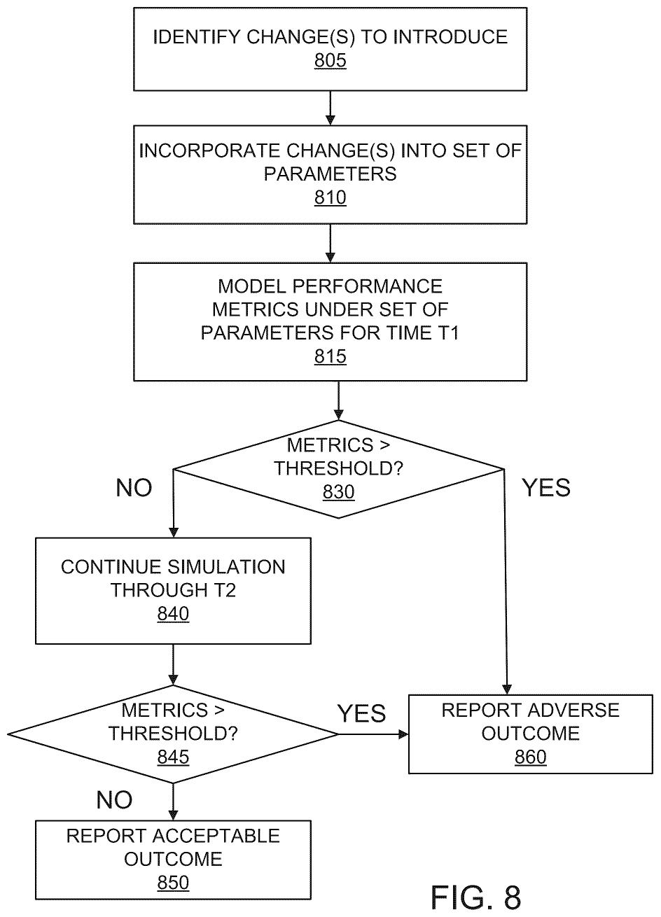

Operations at this stage (625) include various methods of analyzing the emulation results, including discovering changes to performance metrics, discovering risks of adverse outcomes, and building and computing further scenarios for emulation. Further, the results of the previous stage (620) may be quantified and qualified in a number of ways, including assessing the result for each scenario; combining scenarios to determine interventions. A method of determining whether an adverse outcome has occurred is described below with reference to FIG. 8. Further, one method of diagnosing an emulated manufacturing system model to determine the cause of adverse effects is described below with reference to FIG. 9.

### Stage 6 Predict the New Behavior Patterns with the New Dynamic Complexity using the Emulator (630)

In response to recommended changes to the manufacturing system model provided in the previous stage (625), those changes are incorporated into a revised model of the manufacturing system model, and the revised model may be emulated to determine the specific benefits incurred by those changes. Inputs of this stage (630) include the ouputs of the previous stage (625), as well as defined improvement scenarios. Such improvement scenarios may include changes to the manufacturing system model intended improve performance attributes, lower the occurrence probability of adverse or higher-risk manufacturing system states, improve performance metrics and/or lower the risk of one or more adverse outcomes, such as a system or subsystem failure. Such improvements may be suggested as a result of a process as described above with reference to FIGS. 6 and 8-12. In particular, the outputs of this stage (630), following emulation of the manufacturing system model incorporating the suggested revisions, may include an improvement plan specifying remedies or interventions, such as a reallocation of resources, a targeted addition of resources, or a redesign of the services delivered.

Operations at this stage (630) include use of the reference predictive emulator to compute the improvement scenarios and define the plan. Further, the emulator may driven to provide ongoing monitoring of complexity (e.g., over long-term simulated scenarios) to identify degradation due to increase in complexity, determining the impact of such degradation, define actions to address the degradation, and determine the frequency of complexity monitoring and analysis (e.g., continuous, daily, weekly).

### Stage 7 Dynamic Complexity Under Control

As a result of the previous stages, once implemented to identify and take preventive action against adverse outcomes resulting from dynamic complexity within an emulated manufacturing system model, the dynamic complexity of the manufacturing system model can be deemed to be controlled and predictable within an acceptable tolerance. An adverse outcome may be identified based on a rate of change in performance metrics or other characteristics, where one or more of those metrics exceed a threshold rate of change. A singularity may be an example of such an adverse outcome, as well as other rapid changes to the performance or characteristics of a manufacturing system model. Thus, the results, and particularly the proposed changes to the manufacturing system model, can be exported from the model as recommendations to modify and improve the real-world manufacturing system model corresponding to the model.

Inputs of this stage include the outputs, knowledge and experiences of all previous stages, a change management plan, and information on the identified problems and challenges underlying the manufacturing system model. The outputs and ongoing states of this stage include a proposal regarding reporting structure, destination, frequencies, and content; the operations of a control function to implement the plan; and ongoing maturity improvements.

FIG. 7 is a flow diagram illustrating a process of emulating a manufacturing system's performance under varying parameters accounting for dynamic complexity. This process may be incorporated into the process described above with reference to FIG. 6, and in particular expands upon the aforementioned steps of driving an emulator (620) and identifying root causes and defining improvements (625).

Initially, a mathematical model is obtained for emulation (705). The mathematical model may be constructed according to the process described above with reference to FIG. 6 (i.e., steps 605-615), and so may incorporate definitions of both static and dynamic complexity. In order to drive emulation of the model, a first set of parameters (operating conditions) are defined. The first set of parameters may be defined, as described above, to simulate the model as it operates through a given workload (or other set of inputs) over time. With the first set of parameters defined, the model is then simulated under the first set of parameters to generate a corresponding first set of performance metrics (710). The first set of performance metrics may be quantified in a manner as described above. The first set of performance metrics may also include a dimension of time (referred to, for example, as time “T1”), indicating that the results correspond to the first set of input parameters upon simulation for a given length of (simulated) time.

Embodiments of the invention, as described above, provide for emulating a model manufacturing system model through a number of differing scenarios, where the results of such emulations can be analyzed to identify problems and potential solutions for the manufacturing system model. One method of this emulation is to permutate a set of input parameters, by altering one or more values, to generate one or more additional scenarios for emulation. Such selection of differing parameters is described herein with reference to FIGS. 2, 6 and 10. When selecting input parameters to detect an adverse effect resulting from a manufacturing system model's dynamic complexity, a number of variables can be selected for permutation. For example, input parameters can be permutated to simulate a change to the manufacturing system's performance attributes, disruption of a service, failure of a component of the system, or loss of power to one or more components. Further, the length of time over which the model manufacturing system model is emulated may be varied. Such variation in time may be employed, with or without other permutations, to determine whether the input parameters result in an adverse outcome (e.g., a singularity) over a different (e.g., longer) length of time. With one or more variables selected, the first parameters are permutated to generate a second set of parameters (715), and the model is again simulated to generate a corresponding second set of performance metrics (720).

Following obtaining the results of the first and second performance metrics, those metrics may be compared (730) and reported to a user (730) to determine the effect of the different input parameters on the performance of the manufacturing system model. The performance metrics can be analyzed further, as described below with reference to 9, to identify the cause or causes of the modeled results (735). The steps of permutation, simulation and analysis (715-735) may be repeated to determine performance and identify adverse outcomes under a range of scenarios corresponding to different input parameters.

FIG. 8 is a flow diagram illustrating a process for determining whether an adverse outcome has occurred. The process may augment the process of emulating a model manufacturing system model under different parameters as described above with reference to FIG. 7, whereby performance metrics are generated and compared against performance thresholds as the model manufacturing system model is emulated over varying lengths of time.

At an initial stage, changes to a set of input parameters are identified (805) and incorporated into a new set of parameters (810) for emulation. These steps may correspond to step 715 described above with reference to FIG. 7. Further, a time dimension T1 is selected as a simulated time over which to emulate the model manufacturing system model. The model manufacturing system model is then emulated under the new set of parameters over time T1 to obtain performance metrics for time T1 (815). The resulting performance metrics may then be quantified and compared against one or more thresholds (830). For example, performance metrics may be quantified in terms of sustainability (ability to operate while successfully meeting performance goals) and environmental impact, and then plotted over time on a chart. The plotted metrics may then be compared against one or more thresholds corresponding to the relative change in the manufacturing system model's performance metrics to determine whether the change in the manufacturing system model or performance metrics has exceeded an acceptable threshold. If so, then an adverse outcome (e.g., system failure) is reported (860). If not, then the simulation may be continued through to a further time T2 (840).

Due to the dynamic complexity of a manufacturing system model, an adverse outcome may only develop after an extended length of operating time, and may develop despite the failure to predict such an adverse outcome over a shorter length of simulated time. Thus, by extending the simulation through time T2, a model manufacturing system model can be tested more thoroughly to determine whether adverse outcomes result over greater lengths of time. If the resulting performance metrics after time T2 exceed an acceptable threshold (845), then an adverse outcome is reported (860). Otherwise, an acceptable outcome can be reported (850), indicating that the model manufacturing system model exhibits positive performance metrics under the given set of input parameters.

FIG. 9 is a flow diagram illustrating a process 900 for diagnosing a manufacturing system following detection of an adverse outcome. The process may be implemented to analyze the results obtained from the processes described above with reference to FIGS. 6-8. Given at least two different sets of performance metrics generated by corresponding sets of input parameters, the differences between the input parameter sets are identified as the “changes” introduced into the model manufacturing system model (905). Those changes may be viewed as the initial (but not necessarily proximate) cause of an adverse outcome in the performance metrics. For example, those changes may include simulating a change in the manufacturing system's resources or services, failure of a component, or a power disruption.

Next, a component is identified that is most proximate to the adverse outcome (910). For example, a manufacturing system model may exhibit a failure of a single assembly station, which in turn lowers a performance metric (e.g., quantity of products delivered) below an acceptable threshold and raises the risk of a larger, system-wide failure of resources and/or services. Once the initial and proximate causes are identified, a path may then be traced between them (915), where the path encompasses all operations and factors connecting the initial causes to the proximate causes. From this path, a series of nodes and dependencies can be identified in the path, each of which can be considered to have contributed to the causal chain leading to the adverse outcome (920). Each of these components can then be evaluated individually for failures, degradation, and other changes in the manufacturing system model that may have contributed to the adverse outcome (930). With reference to the example above, it may be determined that a suboptimal organization of resources of the manufacturing system, such as an absence of a redundant assembly robot within an assembly line, lowered the manufacturing system's sustainability metric, thereby increasing susceptibility to failure of the assembly line, which in turn increased the risk of failure of a transportation system that transports the products output by the assembly line. In addition, recognizing that other causally-linked factors (outside of this path) may also contribute to an adverse outcome, those other causes may be evaluated in the same manner. With the causes contributing to the adverse outcome identified, those components, as well as the specific problems inherent in each, may be reported for further analysis and remedies (940).

Further description of deconstruction of dynamic complexity and prediction of adverse outcomes, including example applications, is provided in U.S. Pub. No. 2012/0197686, the entirety of which is incorporated herein by reference.

Applying the modeling techniques described above, a range of manufacturing system models can be simulated as a multi-layer mathematical model having layers corresponding to performance attributes, performance metrics rules, and other aspects of the system model. In some embodiments, one or more such layers may be partially or wholly merged, or otherwise reconfigured to accommodate the particular manufacturing system model being modeled. For example, in a relatively simple manufacturing system model, where processes can be described easily with direct relation to the physical components, the process and implementation layers may be implemented in a common layer. Similarly, the implementation and physical layers may be implemented in a common layer.

### Predictive Risk Assessment

The possibility of an adverse outcome, as described above, presents an apparent risk to the operation of a manufacturing system model, or even to the integrity of the manufacturing system model itself. An adverse outcome may be identified based on a rate of change in performance metrics or other characteristics, where one or more of those metrics exceed a threshold rate of change. A singularity, as described above, may be an example of such an adverse outcome, as well as other rapid changes to the performance or characteristics of a manufacturing system model. By identifying outcomes including adverse outcomes and their causes, as described above, embodiments of the invention can enable a manufacturing system model to be reconfigured to avoid such adverse outcomes.

Further, embodiments of the invention can be applied, in a more comprehensive manner, to the identification and avoidance of a range of adverse outcomes. By modeling performance metrics of a manufacturing system model under a range of parameters, the risk of an outcome including an adverse outcome can be ascertained as a probability. The risk can be qualified by a particular adverse outcome, as well as a predefined period of time. Several such risks can be reported simultaneously when warranted.

In an example embodiment of identifying and reporting one or more risks, a multi- layer mathematical model of a manufacturing system model bay be provided as described above. Performance metrics of the multi-layer model may be modeled under plural sets of parameters, where the performance metrics may include a sustainability metric, an environmental impact metric, and/or a risk index. From these performance metrics, one or more adverse outcomes may be identified based on a change or a rate of change in the performance metrics exceeding at least one predetermined threshold. Given the identified adverse outcome(s), a map can be generated to relate the adverse outcome(s) to corresponding instances of the plural sets of parameters. Based on this map, one or more risks can be determined and reported, where the risk(s) define a probability of an outcome including the at least one adverse outcome. Example embodiments providing predictive risk assessment and management are described in further detail below.

FIG. 10 is a state diagram illustrating a process 1000 for manufacturing system risk management in one embodiment. The process 1000 may incorporate a process of modeling a manufacturing system model, determining risks, and deriving solutions to those risks as described above with reference to FIGS. 21-27. The process 1000 may be understood as a cycle that is repeated to improve the perception and management of risk within a manufacturing system model.

Prior to implementing embodiments for determining risk as described above, initial risk perception 2805 (phase one) may be incomplete. Accordingly, in phase two (risk modeling) 2810, information is collected as necessary to perform the deconstruction and causal analysis based on gathered information from experience and benchmarks of similar situations. From this data, the investigation and provocative scenarios that will reveal the risk and singularities may be built. Using the mathematical formulation and the deconstructed characteristics, dependencies and content behavior, a mathematical emulator that represents the manufacturing system model dynamics and the dynamic complexity is delivered. Using this emulator, scenarios can be deployed under different patterns of initial conditions and dynamic constraints to identify the risk and the conditions under which the risk will occur, as well as the possible mitigation strategies. The emulator can be continuously updated to replicate any changes that may happen over time with impacts on the problem definition, due to the evolution of dynamic complexity, environmental changes or content dynamics. Success is enhanced by the ability to keep the emulator representative, accurate, and able to capture all risks with sound projection of predictions.

After building the emulator in phase two 2810, in phase three 2815 (risk discovery), modified scenarios are run to identify possible risks. By modifying the parameters of each scenario within the emulator, one by one, by group or by domain, to represent possible changes, one may extrapolate each time the point at which the manufacturing system model will hit a singularity and use the corresponding information to diagnose the case. The emulator supports risk categorization based on the severity of impact, the class of mitigation, and many other characteristics that support decision making such as urgency, and the complexity and/or cost of implementation of mitigating actions.

For each of scenario, the ripple effect is particularly important to results interpretation. By using perturbation theory as the analytical vehicle to represent manufacturing system model dynamics involving direct and indirect effect on components, as well as trajectories representing sequence of components, the ripple effect is exerted on tightly or loosely coupled interactions.

Other scenarios may be created during this phase 2815 to explore viable and proactive remedial options that secure an acceptable risk mitigation strategy and allow the manufacturing system model to be fixed prior to realizing negative outcomes caused by an eventual risk. This last dimension may be considered crucial in risk management, which supposes that most of the risk is discovered during this phase—including risks generated by dynamic complexity.

Mitigation is the identification, assessment, and prioritization of risks as the effect of uncertainty on objectives followed by coordinated and economical application of resources to minimize, monitor, and control the impact of unfortunate events or to maximize the realization of opportunities. Risk management's objective is to assure uncertainty does not deviate the endeavor from the manufacturing system's performance. Thus, in phase four 2820, the information derived in the previous phases is implemented to mitigate risk to the manufacturing system model. The risk is identified and diagnosed, and then remediation plans may be built ahead of time to eliminate, eventually reduce or at minimum counterbalance the impact of the risk. It is the application of the knowledge gained in the earlier phases that allows us to be ready with awareness of what may happen and plans of how to remediate the risk. Example embodiments may utilize the knowledge database to continuously monitor manufacturing system models to cover the risk of both the knowns as well as the unknowns (e.g., risks) that are caused by the evolutionary nature of dynamic complexity.

In phase five, risk monitoring 2825, the monitoring process is implemented. Using the database that contains all risk cases generated in phase three 2815 and enhanced with remedial plans in phase four 2820, the manufacturing system model may be put under surveillance using automation technologies. Similar in functionality to what is used for planes, cars, and nuclear plants, the auto piloting capabilities may observe the manufacturing system model in operations to identify eventual dynamic characteristics that may lead to a pre-identified risk situation. If a matching case is found, an alert will be generated and the pre-approved remedial actions will become active.

Each stored case may contain an identifier, a diagnosis, and one or more options for remediation. If the auto piloting manufacturing system model does not find a matching case, but has identified critical symptoms that may cause a risk, the monitoring controller sends back the characteristics to the predictive modeling phase two 2810. The corresponding scenario may be run to estimate the risk, diagnose the case, and propose remedial options, which may then be sent back to the database, enriching the knowledge base with the new case. Using this approach, the auto piloting, monitoring and control manufacturing system model may gradually become more intelligent and exhaustive, which, over time, may serve to considerably reduce the occurrence of risks of adverse outcomes.

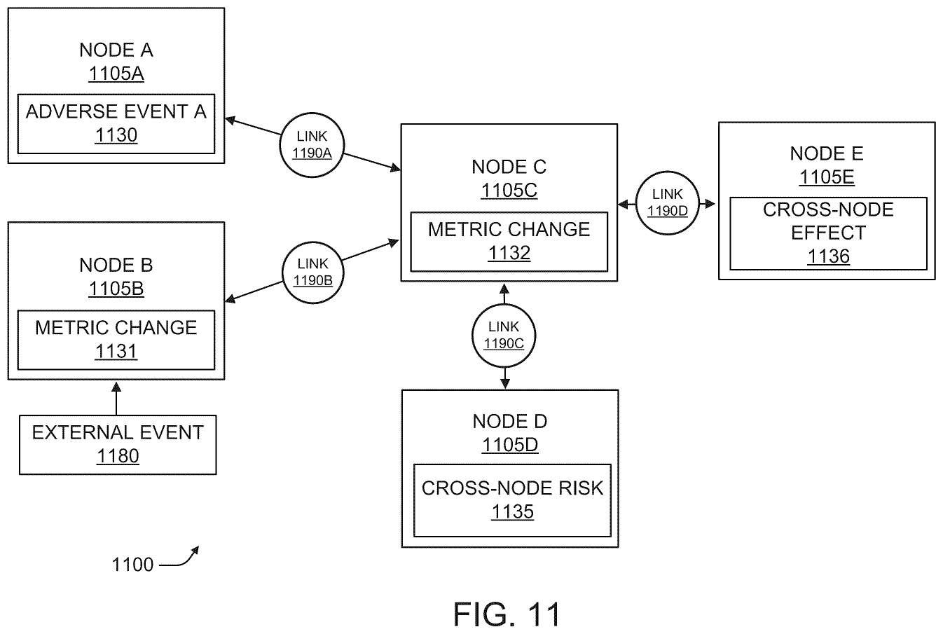

FIG. 11 is a diagram of a portion of a dependency graph 1100 of a manufacturing system model, illustrating propagation of a risk, in one embodiment. The dependency graph 1100 may be implemented in the resource graph 130 and/or the process graph 140 described above with reference to FIG. 1, and may be generated from a process of generating a manufacturing system model as described above. The portion of the dependency graph 1100 shown here may be a subset of a larger dependency graph, wherein the elements of the dependency graph 1100 (nodes and links) are configured based on the causal relation between elements of the system model and performance attributes that they represent. For example, each of the nodes 1105A-E may represent a respective physical resource or a service, wherein some or all of the nodes may have one or more properties (e.g., a variable or static value of the performance attribute), and some or all of those properties may be affected by other nodes via links 1190A-D. The links 1190A-D may represent a causal (e.g., functional or mathematical) relation between the properties of one node and the properties of another. The performance metrics described above may be represented by respective nodes, or may be calculated based on the properties of one or more other nodes. Further examples of dependency graphs as manufacturing system models are described below as exemplifications. For example, nodes 1105A and 1105B may represent different assembly robots of an assembly line, and the values of each node 1105A-B are causally linked to node 1105C via links 1190A-B, wherein node 1105C represents a power supply configured to power both of the assembly robots. The node 1105C, in turn, may be causally linked to nodes 1105D, 1105E, which may represent other resources powered by the power supply or an electric grid supplying the power supply.

In the example shown in FIG. 11, the dependency graph 1100 relates a cross-node effect 1135, occurring at node D 1105D, to the nodes, events and performance metrics that substantially contribute to the cross-node effect 1135. Such elements may be selected for inclusion based on a number of factors, such as “but for” causality, proximate causality (e.g., contribution to the risk above a predetermined threshold), or occurrence of an event/performance metrics that are correlated with occurrence of the cross-node effect above a predetermined threshold. Optionally, the dependency graph 1100 may include additional cross-node effects (e.g., cross-node effect 1136 at node E 1105E) that are partially or fully correlated to occurrence of the cross-node effect 1135.

Though emulation of the multi-node complex through permutations of parameters (as described above with reference to FIGS. 6-9), it may be determined that the cross-node effect 1135 is primarily caused by two influencers: 1) an adverse outcome 1130 occurring at node A 2205A, and 2) an external event 1180 exerting a change in performance metrics 1131 at node B 1105B. It may be determined that both influencers are required to cause the cross-node effect 1135, or that one influencer (absent the other) is sufficient. The adverse outcome 1130 exhibits as a change in performance metrics at node A 1105A, which propagates via link 1190A to node C 1105C. Likewise, the external event 1180 exhibits as a change in performance metrics at node B 1105B, which propagates via link 1190B to node C 1105C. This propagation causes a change in performance metrics 1132 at node C 1105C, which, in turn, propagates via link 1190C to node C 1105D, causing the cross-node effect 1135 to occur. The change in performance metrics 1132 may also propagate via link 1190D to node E, causing the additional cross-node effect 1136. Thus, the dependency graph 1100 relates a cross-node effect to its causes as well as other effects of those causes. The dependency graph 1100 can be presented to a user to aid in preventing or mitigating the cross-node effect 1135, or may be utilized to identify modifications to the complex (e.g., remedial actions) to prevent or mitigate the cross-node effect 1135.

Example indicators or risk exhibited by a manufacturing system model may be referred to as a Dynamic Complexity Indicator (Dycom) and a Risk Index (RI). Dycom and RI may be implemented in the embodiments described above with reference to FIGS. 1-11, and are described in further detail with reference to US Published Application No. 2020/0175439, the entirety of which is incorporated herein by reference.

### Risk Control Approach

The starting point of risk management, in example embodiments, is the analysis following the causal deconstruction of a manufacturing system model:
A) Discover the enviornoment, its dynamics, the infleuncers that may provok a change, the key performance indicators and the goals in terms of performance attributes, performance metrics and/or risk of adverse outcomes.
B) Collect the detailed (static) complexity elements: process flows, structures, confugurations, technologies and geography. Understand the dynamic complexity: dependencies, interactions, combinatorial, operating models.
C) Build the Mathamatical Predictive dynamic complexity emulator through a top/down hierarchical constructs that will show: organizational, logic and physical views of the system (static complexity) and dependencies, feedback, combinatorial parameters patterns (dynamic complexity).
D) Computing the mathematical model will produce the key perormance indicators derived from the computation of performance metrics and risk of adverse outcomes.
E) After a proper validation of accuracy and precision, the emulator will be used to test scenarios and build the knoweledge base:
   a) By changing the intial conditions (e.g., performance metrics via sets of parameters), dependencies and/or infrastructure, environment, and parameters, other adverse events and singularity points may appear and a chaos point may start forming.
   b) By building and compute situational scenarios that may result from the feedback process.
   c) By benchmarking solutions (remedies and interventions) and providing comparisons for decisions.
   d) By providing the necessary knowledge for remedies and real-time intervention.
   e) All along an important number of knowledge items will be derived and populating the knowledge base: come of these items may be known; but most interesting lot of these items may reveal unknown knowledge that have not been observed yet.
   f) Prescribe remedies/interventions based upon an informed decision. By using the knoweldge items collected during the previous phases, the manufacturing system model can be controlled to match an eventual situation with one of such knowledge items.
   g) Therefore, the approach covers the situation now (curative) and the future (proactively): Now, by continuously monitoring and improving the manufacturing system model via remedies/interventions, and in the future by continuously creating new scenarios and identifying the limits, then eventually discover new risks of adverse outcomes and finding the way to bypass those risks.

Such an approach may provide performance professionals a platform to control, plan and identify ideal outcomes for a manufacturing system. In short, both goals of reducing uncertainty, and proactively estimating and fixing problems. Long-term machine learning process will start by modest coverage of process proactive fixing to become over time an intelligent platform that will be able to deliver fast and comprehensive recommendations for right time fixing.

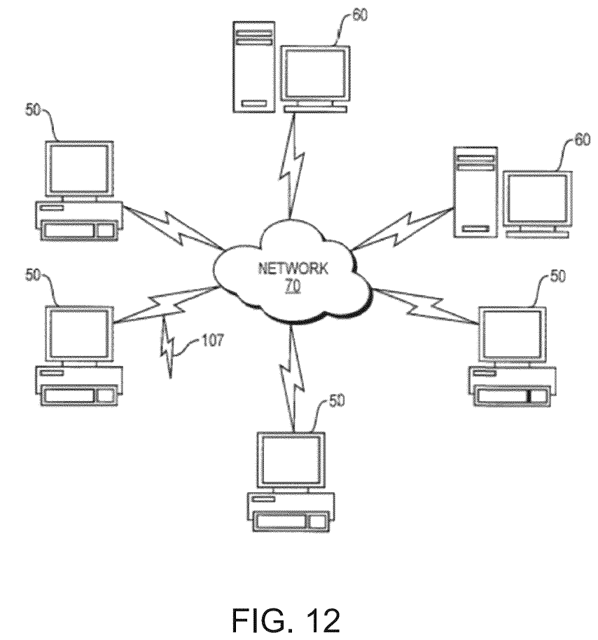

FIG. 12 illustrates a computer network or similar digital processing environment in which embodiments of the present invention may be implemented. Client computer(s)/devices 50 and server computer(s) 60 provide processing, storage, and input/output devices executing application programs and the like. The client computer(s)/devices 50 can also be linked through communications network 70 to other computing devices, including other client devices/processes 50 and server computer(s) 60. The communications network 70 can be part of a remote access network, a global network (e.g., the Internet), a worldwide collection of computers, local area or wide area networks, and gateways that currently use respective protocols (TCP/IP, Bluetooth®, etc.) to communicate with one another. Other electronic device/computer network architectures are suitable.

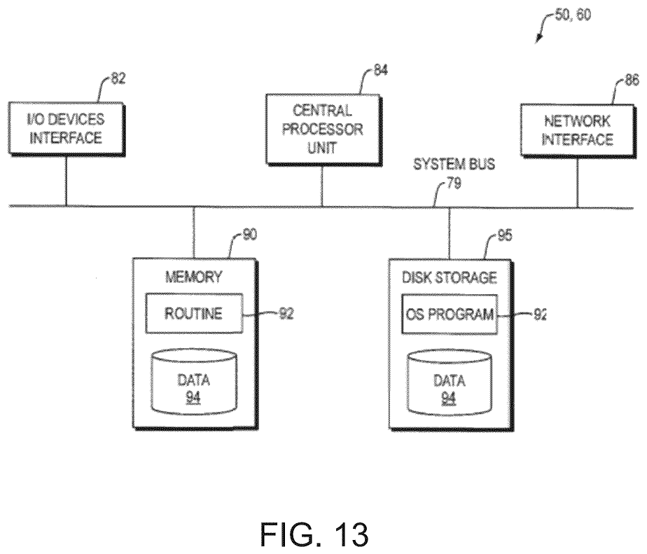

FIG. 13 is a diagram of an example internal structure of a computer (e.g., client processor/device 50 or server computers 60) in the computer system of FIG. 8. Each computer 50, 60 contains a system bus 79, where a bus is a set of hardware lines used for data transfer among the components of a computer or processing system. The system bus 79 is essentially a shared conduit that connects different elements of a computer system (e.g., processor, disk storage, memory, input/output ports, network ports, etc.) that enables the transfer of information between the elements. Attached to the system bus 79 is an I/O device interface 82 for connecting various input and output devices (e.g., keyboard, mouse, displays, printers, speakers, etc.) to the computer 50, 60. A network interface 86 allows the computer to connect to various other devices attached to a network. Memory 90 provides volatile storage for computer software instructions 92 and data 94 used to implement an embodiment of the present invention (e.g., the processes and data structures described above with reference to FIGS. 1-11). Disk storage 95 provides non- volatile storage for computer software instructions 92 and data 94 used to implement an embodiment of the present invention. A central processor unit 84 is also attached to the system bus 79 and provides for the execution of computer instructions.

In one embodiment, the processor routines 92 and data 94 are a computer program product (generally referenced 92), including a non-transitory computer-readable medium (e.g., a removable storage medium such as one or more DVD-ROM's, CD-ROM's, diskettes, tapes, etc.) that provides at least a portion of the software instructions for the invention system. The computer program product 92 can be installed by any suitable software installation procedure, as is well known in the art. In another embodiment, at least a portion of the software instructions may also be downloaded over a cable communication and/or wireless connection.

### Key Performance Indicators

Manufacturing excellence is achieved by aligning the conception and execution of manufacturing procedures and processes with key performance indicators (KPIs) that support company priorities and meet the objectives of various stakeholders. As such, KPIs provide a way to measure and communicate the status of all manufacturing decision-making and change management activities from strategy and design to operations and logistics. KPIs at both local and global levels, provide stakeholders with a way to identify an ideal state of manufacturing, compare remedial options that provide a path to achieve that ideal state and execute plans with confidence in the outcome

Example embodiments can be configured to model one or more KPIs of a manufacturing system by incorporating the KPIs as performance metrics. Example KPIs that may be tracked as performance metrics include the following:
a) Throughput=# of Units Produced/Time (hour or day) measures how much a machine, line, or plant can produce over a specified time period.
b) Cycle time=Process End Time—Process Start Time measures the average amount of time it takes to produce a completed product, each individual component of the final product, or deliver a completed product to the end user. It can help analyze the efficiency of a manufacturing process on the macro scale, as well as determine inefficiencies on a micro scale.
c) Inventory Turns=Cost of Goods Sold/Avg. Inventory measures how many times inventory is sold over a specific time period and helps indicate resource effectiveness.
d) Production Attainment=# of Periods Production Target Met/Total Time Periods measures production levels over a specific time period and calculates what percentage of the time a target production level is achieved.
e) Avoided Cost=Assumed Repair Cost+Production Losses−Preventative Maintenance Cost is an estimate of how much money you saved by spending money. For example, how much money is spent on machine maintenance vs. repair cost if a machine were to break down, plus the lost production value associated with the repair downtime.
f) Downtime to Operating Time=Downtime/Operating Time is a manufacturing metric that can be used to measure the effectiveness of machinery maintenance and the machine itself.
g) First Pass Yield Rate=Quality Units/Total Units Produced calculates the percentage of products manufactured to specification the first time through the process. This means that they do not require any rework or become scrap.
h) Overall Equipment Effectiveness (OEE)=Availability*Performance*Quality. A score of 100 percent means that manufacturing occurs 100 percent of the time, at 100 percent capacity, at a 100 percent yield (i.e., no defective parts).
i) Capacity Utilization=Actual Factory Utilization/Total Productive Capacity measures the amount of capacity being utilized as a function of total capacity available
j) Manufacturing Cost Per Unit=Total Manufacturing Cost/# of Units Produced takes into account all costs associated with production and divides the cost by the number of units manufactured. Typical costs include materials, overhead, depreciation, labor, etc.
k) Energy Cost Per Unit=Total Energy Cost/# of Units Produced measures the total cost of energy spent over a period of time and divides it by the number of units produced in that time frame.
l) CO2 Emissions=Activity*Emission Factor measures the amount of carbon dioxide (CO2) emitted for a given activity.

To make good decisions, manufacturing stakeholders must be able to realistically analyze potential outcomes, benefits, and risks associated with various options. Yet, some decisions must be made without the benefit of experience or historical data. This is especially true for any new activity which may be influenced by complex or unknown dynamics. In such cases, manufacturers are looking for new methodologies and generative AI technologies that fill the knowledge gaps to support smarter decisions and proactive business practices.

Example embodiments help manufacturers deal with modern business dynamics, which have become too complex to manage using experience or data-driven decision support tools. By providing a digital experimentation platform that can be used to continuously adapt to change, identify limits, proactively find and fix any problems, and take advantage of opportunities, example embodiments helps manufacturers deal with a multitude of different, competing issues that must be intelligently managed to reduce waste, increase production profitability, improve sustainability and gain a competitive edge.

Example embodiments can calculate metrics that help manufacturers discover the root cause of any problems or predict the future impacts of any changes in the manufacturing process being studied. Workload and classes, service quality, and cost are three global dimensions that can be measured. Based on as-is or to-be scenario analysis, example embodiments can compute metrics that appear in the reporting dashboards. These metrics provide stakeholders with a quantitative as well as qualitative view of system health, risk, and opportunities for improvement of existing or proposed manufacturing activities and/or designs. Each dimension considers low-level contributions to compute their influence through the graph of interdependencies.

Our experience in manufacturing optimization spans a wide spectrum of cases that differ in criticality, complexity, and scope. In each instance, we have successfully applied unique and efficient predictability and portability for both operations and strategic decisions. Although each case varies in definition and complexity, our investigations reveal requirements that span the following categories:
a) Optimize throughput, while maintaining the target quality of the product.
b) Minimize the impact and destruction of consequential generated errors.
c) Minimize production-line errors and build adaptive lines and structures of defense.
d) Select the right infrastructure with associated flexibility that could be involved in the designs—in some cases, we are able to integrate with Computer Aided Engineer (CAE) implementations.
e) Test options for adaptable procedures to permit flexible, evaluated production design.
f) Minimize production cost and achieve optimal cost pricing to achieve the desired return on investment (ROI).
g) Facilitate testing market expansion scenarios.
h) Optimize the supply chain stages and the end-to-end service including automation options.
i) Deliver preventive maintenance.
j) Reproduce possible errors through predictive analysis.
k) Identify consequential errors and fix errors.
l) Identify and categorize errors in terms of the 3-axis (productivity, quality, and cost), and rate based on criticality.

### Manufacturing System Deconstruction

Manufacturing is the production of goods from materials, parts, and components. Goods may be produced one by one, in batches, or on demand using manual or highly automated production lines composed of time-critical processes. Each manufacturing process is comprised of a given number of interdependent sub-processes, systems, assets, and components that interoperate to execute a series of steps. Each step may be implemented using logical or physical production components—for example, robots, conveyors, automation, industry wafers, assembly facilities, and monitoring/testing mechanisms. And each manufacturing process is comprised of lower-level systems, assets, components, and subcomponents that have their own characteristics and dependencies. At any time, a subcomponent malfunction will cause the malfunctioning of higher-level components, which is then induced and propagated to higher-level production lines or entire processes.

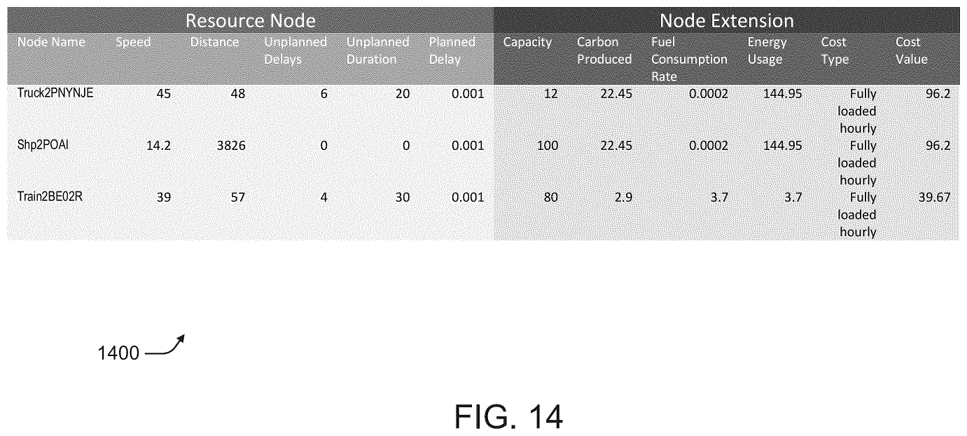

FIG. 14 is a table 1400 representing a plurality of resource nodes. With reference to FIG. 1, each node of the resource graph 130 may correspond to an entry of one or more tables such as the table 1400 to define the properties of each of the physical resources represented. The table 1400, for example, stores entries for a number of transportation resources of the manufacturing system 105. Accordingly, the columns of the table 1400 store entries defining properties relevant to the transportation services provided by the resources, including speed, distance, unplanned delays, unplanned duration, and planned delay.

### Node Extensions

A section of the table 1400, referred to as a “node extension,” can store additional properties useful for modeling particular performance metrics, such as capacity, carbon produced, fuel consumption rate, energy usage, cost type, and cost value. In one example, node extensions may be divided into five categories of information: General, Green, Availability, Failover and Cost. Node extensions may allow additional variables for Vehicle and Transport type nodes, for example, and can be attached to any node in the implementation view. An summary of example node extensions include:
1) General: The general category contains variables dealing with space.
   a) Transport Capacity: The transport capacity variable is the maximum capacity of the node. It is used to establish the maximum capacity of the node. As an example: A container ship that this node represents has a maximum capacity of 200 containers or a truck has a maximum capacity of 40 pallets. (Integer value)
   b) Reserved Capacity: The reserved capacity of the node is the maximum usable capacity of the node. It is used to establish the maximum available capacity for use. To continue the example, a container ship may have a maximum capacity of 200 but only 10 are available for use. Likewise, a truck may have a maximum capacity of 40 and the value of 40 would be fully available. (Integer value)
   c) Space Requirements: This is the floor space requirement for the node. It is currently documentation and is not included in any output at this time.
2) Green: The green category contains variables dealing with energy and carbon emissions.
   a) Carbon Produced: The carbon produced is the number of kilograms of carbon produced per liter of fuel. The value used for this variable should be from a reputable source, EPA, University Lab's, or engineering firm.
   b) Fuel Consumption Rate: The rate of fuel consumption should be presented in kilometers per liter (km/l). This depends on the type of transport and can usually be found in some form or other. Some conversion will likely be required when use airplane and ship as fuel usage is in much larger volumes, but conversion tools are available on-line.
   c) Energy Usage: This is the number of kilowatt hours (kwh) of energy produced per liter of fuel. As with carbon produced this value should come from a reputable source for the fuel type.
   d) Heat Emission: Heat emission is the amount of heat produced per liter of fuel measured in British Thermal Units (btu). It is another metric for energy consumption.
3) Availability: The availability category contains variables used for dealing with the dependability/reliability of the node.
   d) Mean Time Between Failure (MTBF): MTBF is the expected time between failures for the node. It is specified in seconds.
   e) Mean Time to Repair (MTTR): MTTR is the expected time to return the node to service once a failure has occurred. It is specified in seconds.
   f) Node Expected Up Time: This variable is the amount of time in contiguous seconds that the node is expected to be available for use.
   g) Node Service Level: The contractual service level specified by the client. It is a percentage value.
4) Failover: In conjunction with the variables of the availability tab the failover provides variables for assigning nodes to become available should failure occur.
   h) Failover Provided: This is a variable that denotes the presence of a failover is available. (Boolean, 1 or 0)
   i) Failover Target: This variable identifies the node that acts as the failover for the current node that the extension is being created for. The node is selected from a dropdown list of possible nodes.
   j) Failover Delay: The delay is the amount of time it takes for operations to be fully established on the failover target. It is specified in seconds.
5) Cost: The cost tab has variables that allow for assigning dollar cost to the node.
   k) Cost Provided: This is a variable that denotes the presence of a cost value. (Boolean, 1 or 0)
   l) Cost Type: This variable is a description of what the dollar value of cost represents. This variable is selected from a dropdown list of possible types.
   m) Cost Value: This variable is the dollar value to be used with the node.

The recursive effect due to the interdependencies of resources and services creates challenges that are difficult to capture unless the system is represented and reproduced through detailed analysis of the manufacturing system, as wide and as deep in sophistication as possible. One important concepts in systems theory is the notion of interdependence between systems (or subsystems). To model a nonlinear system with sufficient accuracy and reproducibility, these interdependencies must be captured in the mathematical formulation.

When modeling a manufacturing process, it is common to be missing data necessary to explain key phenomena through which independent variables interact to produce complex and synergetic nonlinear effects. Therefore, the chosen modeling method must address this lack of a priori knowledge that explains the nonlinearities in the relations between variables. That is precisely the idea of building a mechanistic mathematical twin: to represent production line dependencies constituents as well as calling upon the interdependencies produced through the contributions of lower-level twins.

The analytical solution described herein translates system dynamics into a mathematical expression, which delivers the same metric values that would have resulted if real system measurements were taken under the same set of initial conditions. Once validated, the system of equations can be reliably used for predictive and prescriptive analysis of the system being studied without a continuous feed of new data.

### Digital Twin

To make good decisions, manufacturing stakeholders must be able to realistically analyze potential outcomes, benefits, and risks associated with various options. Yet, some decisions must be made without the benefit of experience or historical data. This is especially true for any new endeavor or system which may be influenced by complex or unknown dynamics. In such cases, mechanistic digital twin technologies can fill the knowledge gaps to support smarter decisions and proactive business practices.

Through mathematical cloning, a mechanistic digital twin provides manufacturers with a virtual representation of the fit, form, and function of a real-world as-designed, as-built, or as-maintained manufacturing process, product, or asset. A digital twin that uses partial differential equations (PDEs) as the basis of its mathematical solution is robust enough to be representative of an object, product, piece of equipment, person, process, supply chain, or even a complete business ecosystem.

Once the mechanisms of the system are captured in the digital twin, users can compute the model and determine causation between many-to-many time-dependent relationships and interdependencies for millions of connections. The twin calculates missing values and accurately predicts what would happen in the real-world environment under changing conditions. We call this algorithmic intelligence, and it is what makes the approach dependable for highly critical decisions in dynamically complex manufacturing use cases.

A digital twin can be used to understand, predict, and optimize its real-world counterpart's performance and operational risks. While virtual models are conceptual in nature, the algorithmic intelligence derived from the twin provides an accurate digital representation of real events that could happen under a given set of circumstances—regardless of whether those events have occurred. This provides an experimentation platform where smart decisions and innovation can happen in a virtual world, free from physical prototyping costs and the time limitations of a traditional approach. Adjustments can be made to the digital twin to see how the system would change in real life before making any changes to the operational system.

The advanced analytics and scenario analysis capabilities of a mechanistic digital twin can help manufacturers dramatically increase productivity and reduce downtime, maximize the use-life of machinery, detect potential problems before they occur, and take corrective action quickly.

Example embodiments can improve manufacturing operations in several ways:
a) Product Design: Digital twins can be virtual prototypes during the design phase and test different designs options before investing in an optimal prototype. This saves time and cost by reducing the number of iterations required to get the product into production.
b) Process Optimization: Data from a manufacturing line combined with intelligence gained can be used to anticipate and analyze important performance indicators. Adjustments to the digital twin can identify new ways to optimize production, discover weaknesses, and help with root-cause analysis.
c) Quality Management: Using sensitivity analysis to monitor and respond to risk during production is essential for maintaining top quality and eliminating rework. Embodiments can model every part of the production process to identify potential problems and find opportunities to use better materials or processes.
d) Dynamic Certification: Innovations, such as artificial intelligence, advanced robotics, automation, and new modes of human-machine interaction, introduce novel challenges that static certification processes cannot address. Embodiments can be used to continuously monitor and respond to quality and safety compliance gaps that arise over time due to the complexity of adaptive products, services, and systems.
e) Supply Chain Management: Supply chains and logistics/distribution teams can track and analyze key performance indicators, such as packaging performance, fleet management, and route efficiency. Embodiments especially useful for optimizing just-in-time or just-in-sequence production and analyzing distribution routes.
f) Predictive Maintenance: Embodiments can create a digital twin for individual equipment or manufacturing processes to identify issues that indicate the need for preventative repairs or maintenance before a serious problem occurs. Embodiments can also help optimize load levels, tool calibration, and cycle times.
g) Reporting and Collaboration: Metrics make it easy to share intelligence across disciplines, enabling collaboration, improved communication, and faster decision- making. Engineering, production, sales, and marketing can all work together, using the same data, to make more informed decisions.
h) Customer Satisfaction: Embodiments can be used to deliver insights into product performance, distribution, and end-user experience. This intelligence can be used to help engineers and designers improve customer experience with the product through quality control, customization, and ease of use.

### Mathematical Solution

Because computational challenges and missing values persist when dealing with nonlinear systems that contain multiple interacting networks, numerical solutions will become necessary at some point in the analysis. The perturbed graph solution used covers the spatiotemporal evolution of nonlinear systems by expressing and solving Euler-Lagrange partial differential equations (PDEs) through tensor factorization. This method efficiently encapsulates all characteristics, dynamic behaviors, and dependencies among system components to reproduce the nearly exact behavior and adhere to all the rules of the system being mathematically emulated. The resulting analysis enables users to explore prospective cases and have confidence in the system's representation to support highly critical decisions.

As defined herein, the twin represents the graph of connections between all manufacturing components. Each is represented as a mathematical partial derivative that depicts its characteristics and contribution to the end-to-end performance and time. Graph theory provides a mathematical nonlinear data structure capable of representing various kinds of physical structures, consisting of a group of vertices (or nodes) and a set of edges that connect the two vertices.

In practical applications, vertices and edges of graphs often contain specific information, such as labels or weights (such as volume and cost). Many real-life scenarios are better modeled by time-dependent graphs when the edges are activated by sequences of time-dependent elements. Horizontally, behaviors may be driven by dependencies, and vertically, behaviors may result from direct and indirect causes. Finding these causes is sometimes more important than finding the unperturbed solution itself.

The perturbation theory approach involves a dynamic system of Lagrange-like partial differential equations that represent the dynamic behavior of a cost function and a solution that will capture both direct and indirect perturbations around a base of the un-perturbed solution. Conceptually, the solution can be expressed with perturbation theory such that any metric X can be expressed in the form:

$$X = {X}_{0} + {\sum }_{M} {x}_{M}^{( d )} + {\sum }_{N} {X}_{N}^{( i )}$$

### Where:

X₀ is the initial value of a metric (e.g., function or characteristic);
X_{M}^{(d)} is the calculated direct impact due to M causes; the direct impact translates the impact of adjacent node in the graph to a specific node through an edge. and, X_{N}⁽ⁱ⁾ is the calculated indirect impact due to N causes (un-adjacent nodes) exerted on the perturbed function. Such an effect could happen as a first-order perturbation and may also happen as second, third, etc., order perturbations.

The significance has considerable importance as an unapparent statistically uncorrelated effect can play an important effect on the basic function. In different wording, a statistically unlikely risk can appear and even translates sometimes into singularity due to multiple order interactions.

In more detail, consider the following vector: σ=σ(k), where k=1, 2 . . . k and where σ is a function of time and represents the metrics that describe corporate, financial, business, and technology engineering characteristics and behavior.

Further consider that:
a) σ^{(c)} represents the unperturbed value of a metric, or its minimum admitted value for simplicity;
b) σ^{(d)} represents a measure of a perturbed metric due to the direct impact applied on the perturbing function X^{d}; and
c) σ⁽ⁱ⁾ represents the indirect perturbation due to the perturbed effect of metrics against each other or the perturbing function X⁽ⁱ⁾ due to an external impact.

In general, the system of equations that represent the variations can have the form:

$$\frac{d σ}{d t} = {X}^{( c )} ( {σ}^{( c )} ) + {X}^{( d )} ( {σ}^{( d )} ) + {X}^{i} ( {σ}^{( i )} ) \qquad ( 0 )$$

where X^{(c)} represents a basic function.

Further assume that σ′ and σ″ are vectors representing σ through different coordinates, and that σ⁽⁰⁾, σ′⁽⁰⁾, and σ″⁽⁰⁾ represent the unperturbed values of a metric. Then, the first order direct perturbation is:

$$\frac{d σ}{d t} = {\sum }_{k = 1}^{K} ( \frac{d {X}^{( c )}}{d {σ}_{k}} ( {σ}_{k}^{( c )} , {σ}_{k}^{′ ( 0 )} ) {σ}_{k}^{( d )} + \frac{d {X}^{( d )}}{d {σ}_{k}} ( {σ}_{k}^{( c )} , {σ}_{k}^{′ ( 0 )} , {σ}_{k}^{″ ( 0 )} ) ) \qquad ( 1 )$$

and the first order indirect perturbation is:

$$\frac{d σ}{d t} = {\sum }_{k = 1}^{K} \frac{d X}{d {σ}_{k}} ( {σ}_{k}^{( c )} \vert , {σ}_{k}^{′ ( 0 )} ) {σ}_{k}^{( 1 )} + {\sum }_{k = 1}^{K} \frac{d {X}^{( c )}}{d {σ}_{k}^{′ ( 0 )}} {σ}_{k}^{′ ( i )} \qquad ( 2 )$$

This separation seems artificial from a theoretical point of view, but it is natural from a practical point of view, as the origin of perturbation on X^{(d)} and σ⁽ⁱ⁾ are different. Next,

$${σ}^{′ ( 1 )} = {\sum }_{k = 1}^{K} {\sum }_{n = 1}^{m} {C}_{k , n}^{( i )} {e}^{- \sum }$$

C_{k,n}⁽ⁱ⁾ a matrix of numerical vectors, n₁*, n₂*, . . . nₘ* are normalization constants and χ₁, χ₂, . . . , χₘ are the perturbing variables (function in time).

Therefore:

$$\frac{d {X}^{( c )}}{d {σ}_{k}} , {X}^{( d )} ∧ {\sum }_{k} \frac{d {X}^{( c )}}{d {σ}_{k}^{′ ( 0 )}} {σ}_{k}^{′ ( i )}$$

are known functions in time and can solve the two system equations (1) and (2) in the form:

$$\frac{d σ}{d t} = U ( t ) σ + v ( t ) \qquad ( 3 )$$

where U (t) is a square matrix (K×K) and ν(t) is a known vectoral function.

The matrix is determined by:

$$\frac{d Y}{d t} = U ( t ) Y \qquad ( 4 )$$

with

Y(t₀)=I (5)

where I is a unit matrix and therefore equation (3) becomes:

σ=Y(t)σ(t₀)+∫ₜ_{₀}^{t}Y(t)Y¹(τ)ν(τ)dτ

and with X^{(c)}=(X_{K}^{(c)}) U specified in the form

v(t)=))

The formula

$$\frac{d σ}{d t} = U ( t ) σ$$

forms the system of equations equivalent to the un-perturbed expression:

$$\frac{d {σ}^{( c )}}{d t} = {X}^{( c )} ( {σ}_{K}^{( c )} )$$

where the solution Y in equation (4) is known if the partial derivative of the unperturbed problem is computed with respect to the K integration constants such as by determining)) with the condition of equation (5).

A typical manufacturing production plant involves production stations (processes) that have a level of autonomy to deliver part of the manufacturing production activities. Components are linked together through simple or sophisticated connections. A twin represents the graph of connections between plant components, each is represented as a mathematical partial derivative that depicts its characteristics and contribution of the full picture performance and time.

The digital mechanistic twin represents the transformation of real-world manufacturing processes into the language of abstraction that represents the necessary level of details of the base (FIG. 6). This lays the foundation for building a representative twin in mathematics. The components are built as one or several partial differential expressions that yield the same mechanical characteristics of the base and by computation will deliver with high accuracy the same values as in the physical world. High certainty will be obtained by integrating all details properly to each component. In short, the twin will consider all details that produce a given behavior in the real world.

Looking at formula (1) σ is the vector representing the metrics necessary to understand and manage the system complexity and determine the eventual risk. Dependability metric HD metric (also referred to as sustainability metric) shows how the system impacts reliability, performance, safety and cost. Energy ES score indicate the ability of the system to allow modification without negatively altering its service goal. The last metric indicates the tension on resources consumption RI. The computation of the three metrics leads to determine the eventual risk and indicate the scenarios for direction of improvements.

The vectors X^{C}s in formula (1) represent the contributions of the manufacturing components that delivers the production process: X^{C} the basic contribution, X^{d} the contributions from those elements that directly influencing the component through interdependencies of other components and finally Xⁱ represents those contributions exerted by other factors outside the system (e.g., transportations conditions, environmental factors, congestions, or incidents).

For a simplified case, we demonstrate the vectors X's as composed of 4 elements:
a) An automatic demand sorting
b) A production Robotic Facility
c) An Assembly Function
d) A transportation Adaptive Protocol

The solution of the perturbed partial differential equations delivers the perturbed σ vector in the coordinates mentioned above and at different points corresponding to time and space.

### Example Methodology

An example manufacturing system may operate a 4-phase process to provide a service of producing and delivering a product: 1) Automatic Demand Sorting, 2) Production (robotic facility), 3) Assembly function, and 4) Transportation. Each of the processes relies on complex web of subprocesses that may be autonomous, depending on one another or sharing common sets of resources. All represented through a graph of lower-level interdependencies on internal multilevel components (example: ability to apply fault tolerance facilitation, efficient rules of triage and adequate right time testing) or external readiness to adapt to the impact external influencers (traffic options, readiness and availabilities, resources shortages or slowness in action).

Also, any of the processes may undergo perturbing effects in their respective domains: examples the traffic status, the weather conditions, the availability of material, the right choice of scheduling discipline, etc.

Any of the impacts and influences affects not only a component but also their perturbations extend to the full structure through direct, indirect of multiple orders which in turn will impact the contribution of each in time and space. It is practically impossible to account for such influences without a transformation to mathematical expression in perturbed graph theory that make it tractable covering the impact of influences of whatever size and criticality.

The production line is generally time sensitive and predictively should answer overarching objectives to cover:
a) Planned target quality manufactured products per production window of time
b) Robust automated process that avoids frequent manual intervention
c) Efficient assembly that maximizes production, reduce delays, and optimize cost
d) Optimal right time transportation that minimizes excessive delays and jamming

To avoid continuous adjustments (facing production macro and micro incidents) cannot be faced and fulfilled by relying only on previous experience, and rules derived from static accounts, but can only be achieved through a full twining of the real world into full replication of mechanistic characteristics and influences into virtualized set of mathematics-based solution.

Such approach will both represents the perturbed graph but will also provide and environment to test changes that may happen at any level covered by the graph and obtain insight of building the rules that govern the status versus a host of possible scenarios.

TABLE 1
Attributes of processes for modeling

| | Direct | Indirect | Indirect | Production | Role in |
|---|---|---|---|---|---|
| Process | Influence | Influencers 1 | Influencers 2 | Impact | Predictability |
| Automatic | Attributes | Physical | Modes of | Prime | Major |
| demand | Characteristics | Dependencies | Deliveries | | |
| sorting | | | | | |
| Production | Robotic | Mode of | Fault | Prime | Major |
| Robotic | Programming | Design | Tolerance | | |
| Facility | | | | | |
| Assembly | Design and | Working | Org Process | Prime | Foundational |
| Function | Monitoring | Environment | | | |
| Transportation | Routing and | Traffic and | Physical | Secondary | Efficiency of |
| Protocol | Milestones | Incidence | Attributes | | Communication |

Table 1, above, provides an example of process attributes (e.g., attributes 114 of FIG. 1) that may be collected and incorporated into the process graph 140 of a system model 120. The direct and indirect influences inform how the nodes of the processes may be linked to one another and to nodes of the resource graph 130, thereby model the many-to-many interdependencies between processes and resources of the manufacturing system 105.

### Building the Digital (Mechanistic) Twin

1) Build the scope: Here, there are two questions to address:
   a) Why:
      i. Do feel a limit: quantity, quality, cost
      ii. Do hit frequent incidents, challenges, interruptions
      iii. Need to face new demand
      iv. Need to renew and construct new
      v. A business evolution
   b) What:
      i. Part of the platform
      ii. Change the full for more, better, less expensive towards new installation, new concept, more automation, new principles
      iii. Renew the platform
      iv. Build for the future
2) Build the Mechanistic Replication Twin: Building the replication consists of gathering all attributes that express how a component deliver its function. Example, the mathematically reproduce a transportation component, we need the capacity of vehicle, the size of its storage area in whatever unit (e.g., SQU), the speed at different roads. For a robot, we need its throughput, average failures rate, maintenance and error logs. For an assembly line: we need throughput, on-site and external assembled and preassembled pieces and structure.
   a) The interface to build the twin
      i. All attributes are supplied through specific interface that depicts component nature and characteristics
      ii. The interface monitors the conformity to the reference structure and the completeness of data required
   b) The Computation phases
      i. Different engines are necessary to build contributions representing the mechanistic nature per component
      ii. The computation integration is performed by mathematical aggregator that assemble and integrate and verify the results and convergence
   c) The Analysis of metrics and multi-level detailed results
      i. The metrics are computed and exposed to the user through a flexible user interface that allow validation and support for interpretation
      ii. The technology Algorithmic Intelligence (AI) mechanism associated to user case and environment allows the collected validated knowledge ready for use as required and gain time and increase sustainability
   d) The conclusion helps generate additional and as needed management scenarios that help decision makers build and compare various options
      i. Deliver corporate and financial justifications
      ii. Determine the gain/risk factor for each option
      iii. Build the execution plans
      iv. Expected: short, medium, and long plans

### Projections of Production yield versus Demand Intensity

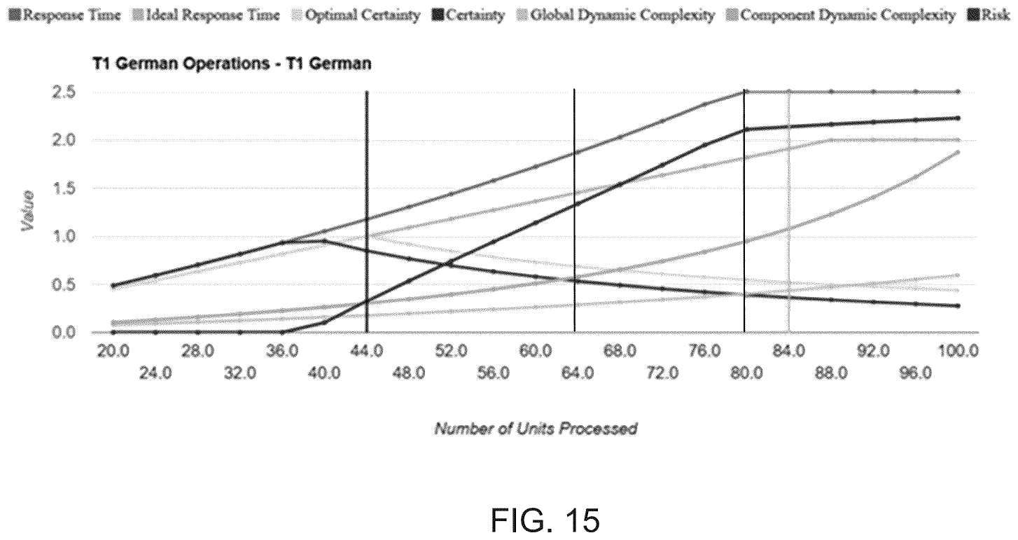

FIG. 15 is a graph illustrating an output of an example embodiment projecting production yield versus demand intensity. In this example, the maximum unity that can be produced in ideal conditions is 44 per hour. Increasing the produced units' dynamic complexity should be compensated through cost escalation. At 64 units per hour, the assembly function becomes at risk, while at 80 units per hour, the risk will become unmanageable.

### Advantages over Conventional Approaches

Other digital twin technologies replicate a simplified view of reality because the modeling method they use can't handle complexity. If for example, a manufacturer wants to create a digital twin of a process composed of 8 million variables, a data-driven digital twin will first exclude as many variables as possible, then use big data to evaluate the relationship between 2 variables at a time. Essentially, the prior-art twin pretends other variables are constant, when in fact they are not. To calibrate or train the model to represent reality, machine learning is applied to analyze thousands or even millions of data sets. This helps improve the predictive accuracy for a known scenario, but the simplification of relationships between variables has a compounding effect.

Due to rounding errors and missing values, the predictive error increases when the twin is used to evaluate scenarios that have never happened before. This makes it difficult to trust the analysis for highly critical decisions, especially for decisions that involve time dependencies or changes that lack historical data.

The number of known or suspected parameters that may influence manufacturing excellence covers multiple scales of variables that differ widely in nature, origin, evolution, and intensity. The only way to capture the contribution of such a diverse set of parameters is to unite them in one mathematical expression.

With the mechanistic approach used by example embodiments, the predictive accuracy of the model that reproduces new or unknown scenarios improves as the characteristics of the system are defined. Big data is replaced with PDEs that express a perturbed graph. PDEs allow for the inclusion of time sensitivity, environmental factors, and any other number of important parameters in the model and provide the rigor necessary to calculate future events exactly, without the involvement of randomness. Complex system dynamics and missing values make this level of model representativeness and reproducibility impossible to obtain using other methods of mathematical or statistical analysis.

By using a mathematical representation in which every variable alters according to a mathematical formula, X-ACT avoids model bias, data integrity and drift issues associated with alternative solutions. Through the use of PDE, X-ACT can calculate future events exactly. The determinism of analysis makes it possible to trust predictions about behaviors that are not represented by existing big data sets.

### Decision Support

To support better design, engineering, assembly, and service decisions, example embodiments create a mechanistic digital twin that mathematically replicates internal and external interdependencies into a single model. The solution can then be used to experiment, identify, and evaluate options as if on a real production process, factory line, asset, or product without any limitations. This is crucial because it is the only way to discover the outcome of an event that has not yet happened, or the root cause of a phenomenon not yet identified to propose the optimal way for implementation.

Example embodiments can compute metrics and displays which details impact its value—including all dependencies at any past, present, or future point in time. The discovery process quantifies the risk, indicates how to minimize the risk, and provides options to improve products or operations using the associated algorithmic intelligence and rules. Over time the algorithmic intelligence produced by example embodiments becomes increasingly sophisticated and leads to wider coverage of known as well as the discovery of previously unknown causal relationships. The ability to discover new causal relationships is highly important as it is the only way to overcome the shortcomings of big data analysis.

Example embodiments may help manufacturers:
a) Integrate production activities into a well-orchestrated flow
b) Avoid any interruptions in the production process
c) Quickly identify and eliminate the root cause of quality issues
d) Remove waste across the value stream
e) Achieve decarbonization and net zero emission goals
f) Align purchase and production decisions with demand
g) Foster communication and flexibility as the cornerstones of lean manufacturing

Using a what-if analysis, it becomes possible to develop an understanding of how a particular risk may evolve under a given set of circumstances. Developing algorithmic knowledge of various evolutionary manufacturing states makes it possible to build rules that can be preventively applied to help identify and/or take actions to avoid any set of circumstances that may lead to a critical outcome for a product or process.

Example embodiments can model all direct and indirect details relating to a manufacturing system. This allows users to discover at any moment in time, which element(s) cause a particular outcome. The approach is expandable to cover millions of connections. Any subset of connections may be the cause of certain risks or promoters of overall improvements—whether the involvement of a parameter is already proven, suspected, or currently unknown.

The dependability (sustainability) metric measures the performance of the end-to-end system against efficiency, productivity and economy benchmarks. This metric can be used to find the operational limits of the system being studied and consistently achieve the best balance between competing objectives. The dependability score of a manufacturing process that is achieving the ideal balance between efficiency, productivity and economy benchmarks is 100%. Comparisons between the current digital twin and any possible future system states proactively expose risks or opportunities for improvements.

For example, what if analysis can show how the dependability score may be impacted by a direct risk, i.e., malfunctioning assembly line components, or indirect risks, like supply chain disruptions or rising costs. Further, the analysis can help decision-makers evaluate potential enhancements. For instance, the dependability score can show whether investments in new automation technologies will achieve the desired cost-cutting and manufacturing capacity improvements.

The energy gradient measures the availability of energy to do the work for which the system was built. As both a quantitative as well as qualitative indication of a gain or loss in energy, the energy gradient is a useful target. When all of a system's energy is absorbed in productive activities, the energy gradient score is 100%. A decreasing energy gradient exposes system disorder that occurs when energy is unavailable to do work and prevents the system from performing at full capacity.

Tracking fluctuations in the energy gradient can help system stakeholders manage risk by identifying any scenarios that cause the system to underperform or improve. For example, a low energy gradient can help stakeholders identify and remove current or future bottlenecks caused by queuing problems that result from mismatched service and processing times. Further, the energy gradient can be used to quantify and plan to manage production risks posed by external factors such as a labor strike or shortages in raw materials.

### Exemplification: Automobile Manufacturing System

The following describes an application of an example embodiment to emulate a multi-national automobile manufacturer. The approach may begin by identifying what the expected use of the emulation will be to establish the scope of the emulator. Once the scope has been identified, we begin identifying the processes used within the scope and begin deconstruction of those processes. This can be an iterative process as new processes can be identified, or processes combined to represent the company operations more accurately. As this is being done the driving factor (intensity) of work to be done by each process can be identified. This intensity represents the workload to be accomplished during an identified period, peak hour, peak day or what the expected emulation window will be.

With the processes identified, the next step is to define the process flow by creating a service process flow diagram for each process. The flow helps identify the underlying resources required for the successful emulation of the process. It additionally distributes the workload to those resources for the emulation of the process.

Once the process flows are defined and the resources to be used are identified the Implementation View can be constructed. Each resource has an action or actions that they perform in support of the process or processes. The amount of productive time and unproductive time that the resource action uses per item/unit being produced needs to be identified.

Using the identified resources, the locations and groupings can then be identified, and the locations placed on the map, groupings at each location are created and finally the resources are added to the group where they are to be identified. The action(s) identified for the resource are applied to the resource by answering the questions when creating the resource node.

Completing the implementation view requires the creation of the network. All resources and all groupings must be connected to the network so that there is a path between all resources and groups and is required for computation.

The final step is creating the connection between each activity in the processes with the resource and action of that resource. After this has been completed any messages defined in the flow can then be defined between activities and their associated actions. The emulation is now ready to compute and check for representativeness.

Examples below are provided for each step in the methodology above and how they are applied within the emulation created. We begin with establishing the scope and move on to process identification and deconstruction followed by defining process flow and actions. From there, we go to resource identification and creation of the implementation. Finishing with linking of the resource actions to the service activities and messages.

### Scope

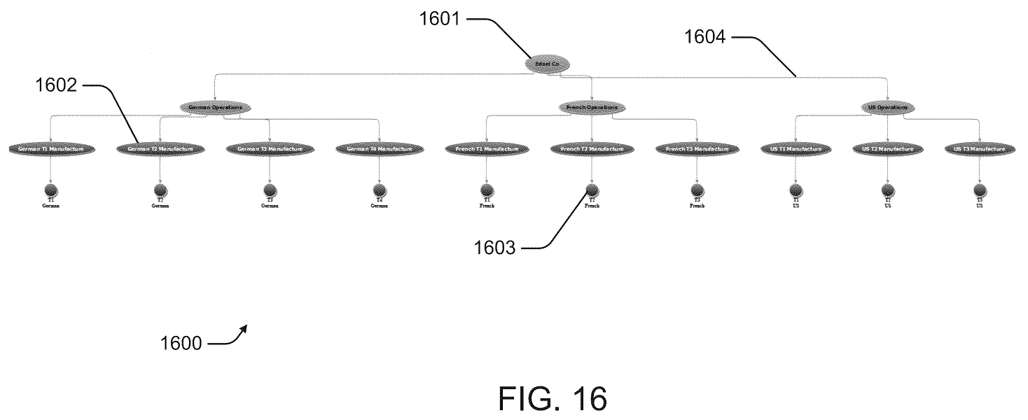

FIG. 16 is high-level service graph 1600 depicting the top-level services provided by the manufacturer. As shown, the auto manufacturer has manufacturing facilities in three different countries, each with an assembly line capable of manufacturing all three models of auto they manufacture. The manufacturer is interested in the impact of shipping models manufactured from one facility to another in a different location to avoid the problems of changing lines over from one model to another as well as availability of parts for construction. Additionally, they are interested in looking at the impact of malfunctions and delays to the lines.

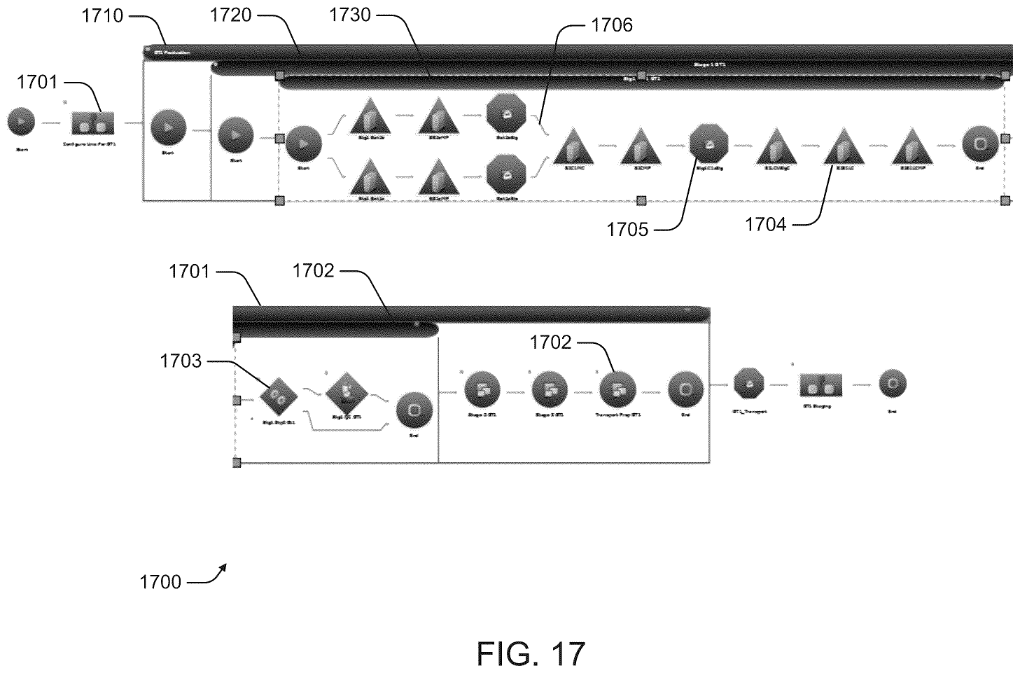

The process graph 1600 includes the following representative components:
a) Corporate object 1601: specifies variables for window duration.
b) Business Entities 1602: the oval shapes in the middle two rows. The greenish colored are accepting the value passed from above. The dark gray have an assigned value.
c) Business Process 1603: The small circles are the business processes. Such processes can be expanded in the Service View to show the detailed process flow as depicted in FIG. 17.
d) Connecting Lines 1604: The lines establish the connection between the three types of objects and has a value referred to as utilization frequency that adjusts the intensity number passed from object to object by the percentage assigned to the line. Example “Germain T1 Manufacture” has a value of 100 if the utilization frequency for the line connecting to the “T1 German” process it receives a value of 10.

### Process Identification

As shown in FIG. 16, each facility is capable of manufacturing all three models T1, T2 and T3 of the manufacturer's autos. While the basic operation of the assembly line is the same for each model the process for each model is slightly different. This means that a process will be defined for each model and will be replicated at each location. FIG. 16 is a “corporate” view showing the processes at the three locations: Germany, France and the U.S.A.

### Process Deconstruction

FIG. 17 illustrates a process graph 1700 for manufacturing a T1 model automobile. The manufacture of the T1 model can be broken down into 3 stages: transportation preparation 1710, shipment 1720, and staging at the destination 1730. In addition, when the line is started if it is being changed over from a T1 model to a T2 or T3 model an optional step can be activated to show that impact. Each stage in the process is broken down into steps which have an activity defined for robots on both sides of the line, command and control systems that monitor and control robots and line and a step for Quality Control at the end of the Stage.

The process graph 1700 includes the following representative components:
a) Service Process 1701: A container for the steps involved in configuring the line.
b) Service Component 1702: A container for the step involved in Transfer Prep.
c) Service Task 1703: A container mainly for activities and other tasks. The icon can be different the shape is always a square on point.
d) Service Activity 1704: The service activity is where a process activity can be associated with a resource action. The icon can be different, but the shape is always a triangle.
e) Service-To-Service 1705: Represents a message definition. It can exist at any level within the graph. A message requires the definition of a producing resource action and a consuming resource action.
f) The lines 1706 between Service nodes work just like the lines in the corporate view. They have a utilization frequency variable for adjust the intensity passed to each node and then on to the actions.

In the flow defined movement is parallel on both sides of the line with (a) robots on one side of the line and (b) robots on the other side. They are passing messages to the control systems to monitor operation and progress. In the transportation preparation step logistics management is identified as well as transport from Germany to local staging, staging in France and staging in the US. This process may be replicated and modified for each model and each location giving us the ability to emulate multiple combinations or options.

### Resource Identification

As the process flow was developed resources 4 basic types were identified.
a) They are Robots of which there were 14 identified, 7 on each side of the assembly line.
   i. BotAct which is the main function of the robot. It has a value for productive time which is the actual time it takes to perform its primary function and unproductive time which is time to position or reset or some other delay. These values are used when defining the action of the robot.
   ii. BotSig is the administrative action of the robot to signal status, it can be used to signal start, completion, malfunction, or any number of things to the controller. As explained above it has a productive time and possible unproductive time for delay.
b) Robot controllers were identified with there being 1 for each a/b pair making 7 controllers. Each robot has 2 actions that they perform,
   i. BotConsume this action is the controller receiving a message from a robot and processing the message. As explained above there is both productive and unproductive time associated with the action.
   ii. BotProduceis this action is for the robot controller to post notifications where needed. It is defined with productive and unproductive time when performing its functions.
c) Three types of transport are identified for transport to either local staging lots or transport to an additional transport for long haul transport to a foreign staging lot. Each transport is defined with a distance, speed and transport capacity for what they are transporting.
d) Five human types are identified by action.
   i. There are 3 QC types each having a different amount of time for their action.
      1) QC1 type takes 300 seconds per action and there are 4 of them 1 in 10 units are checked.
      2) QC2 type takes 600 seconds per action and there are 4 of them.
      3) QC3 type takes 900 seconds per action and there are 4 of them.
   ii. Shipping Logistics is the 4^{th} type of human action. The time per unit is 1000 seconds and there are 8 humans assigned.
   iii. The last human action type is Configuration Support per unit to be processed requires 4200 seconds with 2 humans used to do the processing.

In addition to the resources, 6 locations were identified, three manufacturing locations and 3 shipping ports. Each manufacturing location has two groups defined, one for the manufacturing and the second for the staging of autos. The shipping ports have a single group defined.

The locations may be placed on the map with manufacturing and staging located in Luneburg, Germany, Tours, France and Monroe, Georgia, USA. The ports used by the manufacturer are the Port of Hamburg, Hamburg, Germany, Pot de Saint-Nazaire, Saint-Nazaire, France and Port of Charleston, Charleston, South Carolina, USA. The locations are plotted on a map, and groups may be added to each location.

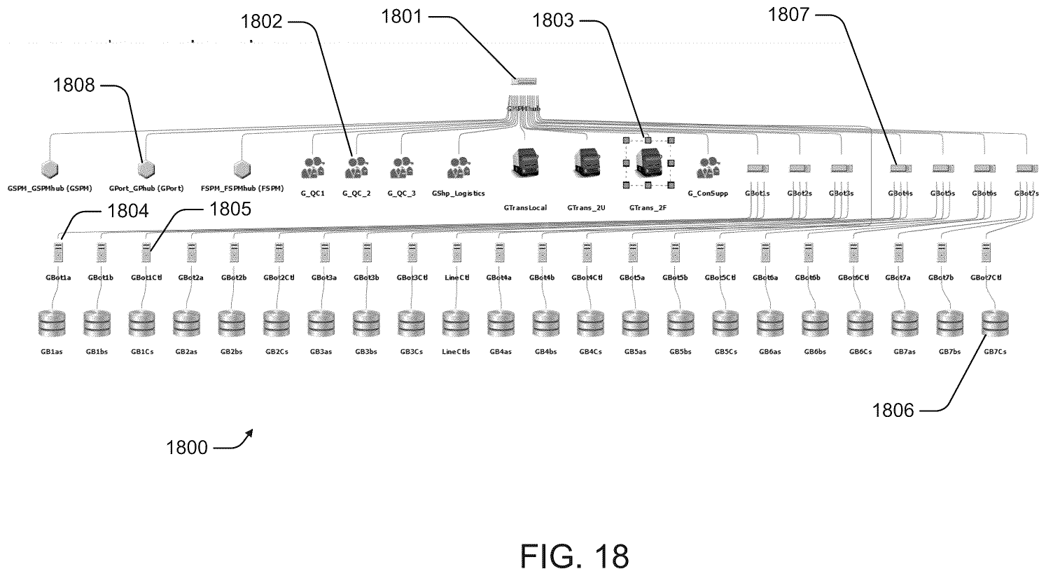

FIG. 18 shows a resource graph 1800. Once the groups are created as described above, the resources can be added to the manufacturing site as shown in the resource graph 1800. A network device is added to each group to allow the defining of the network, which enables the path to be defined between points on the map.

The resource graph 1800 includes the following representative components:
a) Router 1801: The router is the connecting point for the overall network. It has default properties associated as network performance is not at issue in this emulation.
b) Human 1802: A human node has 4 variables, time per action, number of interrupts, duration of interrupts and repetition.
c) Vehicle 1803: A vehicle is a transport for moving units between locations. It has 5 variables, speed, distance, number of interrupts, interrupt duration and repetition.
d) Server (Robot) 1804: A robot is a type of server; it has 2 actions as described earlier.
e) Server (Controller) 1805: A robot controller manages the actions of the robot and reports status. It has two actions defined.
f) Storage 1806: Each Server node requires a connected storage node.
g) Switch 1807: A standard network switch for connecting the robots and controllers.
h) Connector 1808: The connector shows off page connections to other location groups.

### Process to Resource Linking

The final steps are creating the connections between the service process graph (Flow) and the resource action (Group View). This is done by going to the activities in the flow and selecting the Add ACI button. From the lists identify the appropriate action and click add selected. This creates the link between the logical flow definition and the physical implementation.

Once this has been accomplished, if there are any Service to Service's defined in the flow it is necessary to define the message(s) that are to be passed. This consists of giving the message a name and selecting the producing activity and the consuming activity. The message is created in the list and shows the action that will be used. However, if there is more than one action defined for the activity make sure to select the correct one. This completes the emulator definition (i.e., system model) which is now ready for computation through various scenarios.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A computer implemented method of evaluating operation of a manufacturing system, comprising:
obtaining a resource graph defining:
1) a plurality of resource nodes each representing a physical resource of a plurality of physical resources of the manufacturing system, and
2) a plurality of resource links each representing a causal dependency between at least two of the resource nodes;
obtaining a process graph defining:
1) a plurality of service nodes each representing a service of a plurality of services performed by the manufacturing system,
2) a plurality of service links each representing a causal dependency between at least two of the service nodes, and
obtaining a mapping between the service links and the resource nodes, the mapping representing use of the physical resources by the services;
modeling performance metrics of the manufacturing system by simulating performance of the plurality of services as a function of the resource graph and the process graph under plural sets of operational parameters, the modeling including:
1) determining a change in status of the resource nodes over a runtime as a function of operation of the service nodes; and
2) determining a change in the operation of the service nodes over the runtime as a function of the change in status of the resource nodes;
identifying a risk based on the modeled performance metrics, the risk indicating a change in the performance metrics that exceeds a predetermined threshold;
identifying at least one of the plural sets of operational parameters associated with an outcome absent the risk;
determining a modification to the manufacturing system based on the operational parameters associated with the outcome absent the risk; and
updating at least one of the resource graph and the process graph based on the modification.

2. The method of claim 1, wherein the plurality of services include at least one of generating a product, processing a product, and transporting a product.

3. The method of claim 1, wherein the plurality of resource links represent a relationship between an operational capacity of two or more of the resource nodes.

4. The method of claim 1, wherein the plurality of service links represent a relationship between an input and an output of two or more of the service nodes.

5. The method of claim 1, wherein the mapping includes 1) an association between one resource node and multiple service nodes, and 2) an association between one service node and multiple resource nodes.

6. The method of claim 1, wherein the plural sets of operational parameters are distinct from one another by defining at least one of: failure of a resource node, a delay of an service, a modification to the service links indicating a different sequence of operations, and a modification to the service links indicating an alternative mode of operation.

7. The method of claim 1, wherein the plurality of resource nodes each include a respective emission parameter, the emission parameter indicating a rate of pollutant emission caused by the respective physical resource, the method further comprising:
identifying an environmental impact based on the modeled performance metrics and the respective emission parameters.

8. The method of claim 7, further comprising:
identifying at least one of the plural sets of operational parameters associated with a reduced environmental impact; and
determining a modification to the manufacturing system based on the operational parameters associated with the reduced environmental impact.

9. The method of claim 1, wherein the plurality of service nodes each define a subset of the runtime in which the respective service is active and a subset of the runtime in which the respective service is inactive.

10. The method of claim 1, wherein the plurality of resource nodes each define a capacity to perform at least one of the plurality of services during a given time period.

11. The method of claim 1, further comprising:
identifying variation of the risk under the plural sets of operational parameters; and
determining a function relating the performance metrics and the risk based on the variation.

12. The method of claim 1, wherein the performance metrics include a sustainability metric indicating repeatability of a manufacturing process.

13. The method of claim 1, wherein the performance metrics include an energy metric indicating an availability of energy to perform the plurality of services in excess of energy consumed by the manufacturing system.

14. The method of claim 1, further comprising modifying the manufacturing system to incorporate the modification.

15. A computer-readable medium comprising instructions that, upon execution by a computer processor, cause the processor to:
obtain a resource graph defining:
3) a plurality of resource nodes each representing a physical resource of a plurality of physical resources of the manufacturing system, and
4) a plurality of resource links each representing a causal dependency between at least two of the resource nodes;
obtain a process graph defining:
3) a plurality of service nodes each representing a service of a plurality of services performed by the manufacturing system,
4) a plurality of service links each representing a causal dependency between at least two of the service nodes, and
obtain a mapping between the service links and the resource nodes, the mapping representing use of the physical resources by the services;
model performance metrics of the manufacturing system by simulating performance of the plurality of services as a function of the resource graph and the process graph under plural sets of operational parameters, the modeling including:
3) determining a change in status of the resource nodes over a runtime as a function of operation of the service nodes; and
4) determining a change in the operation of the service nodes over the runtime as a function of the change in status of the resource nodes;
identify a risk based on the modeled performance metrics, the risk indicating a change in the performance metrics that exceeds a predetermined threshold;
identify at least one of the plural sets of operational parameters associated with an outcome absent the risk;
determine a modification to the manufacturing system based on the operational parameters associated with the outcome absent the risk; and
update at least one of the resource graph and the process graph based on the modification.

16. The computer-readable medium of claim 15, wherein the plurality of services include at least one of generating a product, processing a product, and transporting a product.

17. The computer-readable medium of claim 15, wherein the plurality of resource links represent a relationship between an operational capacity of two or more of the resource nodes.

18. The computer-readable medium of claim 15, wherein the plurality of service links represent a relationship between an input and an output of two or more of the service nodes.

19. The computer-readable medium of claim 15, wherein the mapping includes 1) an association between one resource node and multiple service nodes, and 2) an association between one service node and multiple resource nodes.

20. The computer-readable medium of claim 15, wherein the plural sets of operational parameters are distinct from one another by defining at least one of: failure of a resource node, a delay of a service, a modification to the service links indicating a different sequence of operations, and a modification to the service links indicating an alternative mode of operation.

21. The computer-readable medium of claim 15, wherein the plurality of resource nodes each include a respective emission parameter, the emission parameter indicating a rate of pollutant emission caused by the respective physical resource, and further comprising instructions to:
identify an environmental impact based on the modeled performance metrics and the respective emission parameters.
